(19) United States
(12) Patent Application Publication
(10) Pub. No.: US 2008/0193871 A1
(43) Pub. Date: Aug. 14, 2008

(54) Positive Resist Composition For Immersion Exposure and Method of Forming Resist Pattern

(75) Inventors: Toshiyuki Ogata, Kawasaki-shi (JP); Hiromitsu Tsuji, Kawasaki-shi (JP); Syogo Matsumaru, Kawasaki-shi (JP); Hideo Hada, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Tokyo Ohka Kogyo Co., Ltd., Kawasaki-shi (JP)

(21) Appl. No.: 11/577,003

(22) PCT Filed: Sep. 30, 2005
(86) PCT No.: PCT/JP05/18138

§ 371 Date: Oct. 26, 2007

(30) Foreign Application Priority Data
Oct. 12, 2004 (JP) 2004-297945

(51) Int. Cl. G03F 7/004; G03F 7/26

(52) U.S. Cl. 430/270.1; 430/322

(57) ABSTRACT

A positive resist composition for immersion exposure that includes a resin component (A) that exhibits increased alkali solubility under the action of acid, and an acid generator component (B) that generates acid upon exposure, wherein the resin component (A) includes a resin (A1) that has alkali-soluble groups (i) having a hydrogen atom, and in a portion of these alkali-soluble groups (i), the hydrogen atom is substituted with an acid-dissociable, dissolution-inhibiting group (I) represented by a general formula (I) shown below [wherein, Z represents an aliphatic cyclic group; n represents either 0 or an integer from 1 to 3; and R¹ and R² each represent, independently, a hydrogen atom or a lower alkyl group of 1 to 5 carbon atoms].

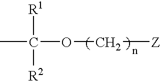

### TECHNICAL FIELD

The present invention relates to a positive resist composition for immersion exposure that is used in a method of forming a resist pattern that includes an immersion exposure (immersion lithography) step, and a method of forming a resist pattern.

Priority is claimed on Japanese Patent Application No. 2004-297,945, filed Oct. 12, 2004, the content of which is incorporated herein by reference.

### BACKGROUND ART

Lithography methods are widely used in the production of microscopic structures in a variety of electronic devices such as semiconductor devices and liquid crystal devices, and ongoing miniaturization of the structures of these devices has lead to demands for further miniaturization of the resist patterns used in these lithography processes. With current lithography methods, using the most up-to-date ArF excimer lasers, fine resist patterns with a line width of approximately 90 nm are able to be formed, but in the future, even finer pattern formation will be required.

In order to enable the formation of these types of ultra fine patterns of less than 90 nm, the development of appropriate exposure apparatus and corresponding resists is the first requirement.

In the case of resists, chemically amplified resists, which enable high levels of resolution to be achieved, are able to utilize a catalytic reaction or chain reaction of an acid generated by irradiation, exhibit a quantum yield of 1 or greater, and are capable of achieving high sensitivity, are attracting considerable attention, and development of these resists is flourishing.

In positive chemically amplified resists, resins having acid-dissociable, dissolution-inhibiting groups are the most commonly used. Examples of known acid-dissociable, dissolution-inhibiting groups include acetal groups such as ethoxyethyl groups, tertiary alkyl groups such as tert-butyl groups, as well as tert-butoxycarbonyl groups and tert-butoxycarbonylmethyl groups. Furthermore, structural units derived from tertiary ester compounds of (meth)acrylic acid, such as 2-alkyl-2-adamantyl (meth)acrylate, are widely used as the structural units containing an acid-dissociable, dissolution-inhibiting group within the resin component of conventional ArF resist compositions, as disclosed in the patent reference 1 listed below.

On the other hand, in the case of the exposure apparatus, techniques such as shortening the wavelength of the light source used, and increasing the diameter of the lens aperture (NA) (namely, increasing NA) are common. For example, for a resist resolution of approximately 0.5 μm, a mercury lamp for which the main spectrum is the 436 nm g-line is used, for a resolution of approximately 0.5 to 0.30 μm, a similar mercury lamp for which the main spectrum is the 365 nm i-line is used, for a resolution of approximately 0.3 to 0.15 μm, 248 nm KrF excimer laser light is used, and for resolutions of approximately 0.15 μm or less, 193 nm ArF excimer laser light is used. In order to achieve even greater miniaturization, the use of F₂ excimer laser light (157 nm), Ar₂ excimer laser light (126 nm), EUV (extreme ultraviolet radiation: 13 nm), EB (electron beams), and X-rays and the like is also being investigated.

However, shortening the wavelength of the light source requires a new and expensive exposure apparatus. Furthermore, if the NA value is increased, then because the resolution and the depth of focus range exist in a trade-off type relationship, even if the resolution is increased, a problem arises in that the depth of focus range reduces.

Against this background, a method known as immersion lithography has been reported (for example, see non-patent references 1 to 3). This is a method in which exposure (immersion exposure) is conducted with the region between the lens and the resist layer disposed on top of the wafer, which has conventionally been filled with air or an inert gas such as nitrogen, filled with a solvent (a liquid immersion medium) that has a larger refractive index than the refractive index of air.

According to this type of immersion lithography, it is claimed that higher resolutions equivalent to those obtained using a shorter wavelength light source or a larger NA lens can be obtained using the same exposure light source wavelength, with no reduction in the depth of focus range. Furthermore, immersion lithography can be conducted using existing exposure apparatus. As a result, it is predicted that immersion lithography will enable the formation of resist patterns of higher resolution and superior depth of focus at lower costs, and accordingly in the production of semiconductor elements, which requires enormous capital investment, immersion lithography is attracting considerable attention as a method that offers significant potential to the semiconductor industry, both in terms of cost and in terms of lithography properties such as resolution.

Currently, water is mainly used as the liquid immersion medium for immersion lithography.

[Patent Reference 1]

Japanese Unexamined Patent Application, First Publication No. Hei 10-161313

[Non-Patent Reference 1] Journal of Vacuum Science and Technology B (U.S.), 1999, vol. 17, issue 6, pp. 3306 to 3309.

[Non-Patent Reference 2] Journal of Vacuum Science and Technology B (U.S.), 2001, vol. 19, issue 6, pp. 2353 to 2356.

[Non-Patent Reference 3] Proceedings of SPIE (U.S.), 2002, vol. 4691, pp. 459 to 465.

### DISCLOSURE OF INVENTION

However, many factors associated with immersion lithography remain unknown, and the formation of an ultra fine resist pattern of a level suitable for actual use remains problematic. For example, when an attempt was made to form patterns finer than 90 nm by applying conventional KrF resist compositions and ArF resist compositions to immersion lithography, either patterns were unable to be formed, or even if formed, the resulting resist pattern shapes were unsatisfactory, with problems including rounding or T-top shapes within the top portions of the resist pattern, and surface roughness within the resist pattern.

The present invention takes these problems associated with the conventional technology into consideration, with an object of providing a positive resist composition for immersion exposure and a method of forming a resist pattern that enable the formation of a fine resist pattern with a favorable resist pattern shape.

As a result of intensive investigation, the inventors of the present invention discovered that by using a resin in which the alkali-soluble groups were protected with a specific acid-dissociable, dissolution-inhibiting group, the above object could be achieved, and they were therefore able to complete the present invention.

In other words, a first aspect of the present invention is a positive resist composition for immersion exposure that includes a resin component (A) that exhibits increased alkali solubility under the action of acid, and an acid generator component (B) that generates acid upon exposure, wherein

the resin component (A) includes a resin (A1) that has alkali-soluble groups (i) having a hydrogen atom, and in a portion of these alkali-soluble groups (i), the hydrogen atom is substituted with an acid-dissociable, dissolution-inhibiting group (I) represented by a general formula (I) shown below.

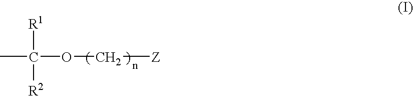

[wherein, Z represents an aliphatic cyclic group; n represents either 0 or an integer from 1 to 3; and R¹ and R² each represent, independently, a hydrogen atom or a lower alkyl group of 1 to 5 carbon atoms]

Furthermore, a second aspect of the present invention is a method of forming a resist pattern using the positive resist composition for immersion exposure of the first aspect, which includes conducting immersion exposure.

In the claims and description of the present invention, the term “structural unit” refers to a monomer unit that contributes to the formation of a polymer. Furthermore, the term “(α-lower alkyl)acrylate ester” is a generic term that describes α-lower alkyl acrylate esters such as a methacrylate ester and/or an acrylate ester. The term “α-lower alkyl acrylate ester” refers to a structure in which the hydrogen atom bonded to the α-carbon atom of an acrylate ester has been substituted with a lower alkyl group. A “structural unit derived from an (α-lower alkyl)acrylate ester” refers to a structural unit formed by cleavage of the ethylenic double bond of an (α-lower alkyl)acrylate ester.

Furthermore, the term “exposure” is used as a general concept that includes irradiation with any form of radiation.

The present invention is able to provide a positive resist composition for immersion exposure and a method of forming a resist pattern that enable the formation of a fine resist pattern with a favorable resist pattern shape.

### BEST MODE FOR CARRYING OUT THE INVENTION

### <<Positive Resist Composition>>

A positive resist composition for immersion exposure according to the present invention can be used in a method of forming a resist pattern that includes conducting immersion exposure, and includes a resin component (A) (hereafter referred to as the component (A)) that exhibits increased alkali solubility under the action of acid, and an acid generator component (B) (hereafter referred to as the component (B)) that generates acid upon exposure.

In this positive resist composition, the action of the acid generated from the component (B) causes the acid-dissociable, dissolution-inhibiting groups contained within the component (A) to dissociate, thereby causing the entire component (A) to change from an alkali-insoluble state to an alkali-soluble state. As a result, during the formation of a resist pattern, when the positive resist composition applied to the surface of a substrate is selectively exposed through a mask pattern, the alkali solubility of the exposed portions increases, meaning alkali developing can then be conducted.

### <Component (A)>

In the positive resist composition for immersion exposure according to the present invention, the component (A) includes a resin (A1) that has alkali-soluble groups (i) having a hydrogen atom, and in a portion of these alkali-soluble groups (i), the hydrogen atom is substituted with an acid-dissociable, dissolution-inhibiting group (I) represented by the general formula (I) shown above.

There are no particular restrictions on the alkali-soluble group, provided it contains a hydrogen atom. Examples of suitable groups include known groups from previously proposed KrF resists, ArF resists, and F₂ resists, such as the groups exemplified in the above non-patent references. Specific examples of these alkali-soluble groups include alcoholic hydroxyl groups, phenolic hydroxyl groups, and carboxyl groups.

In the present invention, the alkali-soluble group is preferably at least one group selected from amongst alcoholic hydroxyl groups, phenolic hydroxyl groups, and carboxyl groups. Of these, alcoholic hydroxyl groups exhibit particularly high transparency relative to light sources with wavelengths of 200 nm or shorter, and also have a suitable level of alkali solubility, and are consequently ideal.

In those cases where the alkali-soluble group is an alcoholic hydroxyl group, then of the various possibilities, alcoholic hydroxyl groups in which the carbon atom adjacent to the carbon atom bonded to the alcoholic hydroxyl group bears at least one fluorine atom are particularly preferred.

The alcoholic hydroxyl group may be simply a hydroxyl group, or may also be an alcoholic hydroxyl group-containing alkyloxy group, an alcoholic hydroxyl group-containing alkyloxyalkyl group, or an alcoholic hydroxyl group-containing alkyl group.

In an alcoholic hydroxyl group-containing alkyloxy group, examples of the alkyloxy group include lower alkyloxy groups. Specific examples of lower alkyloxy groups include a methyloxy group, ethyloxy group, propyloxy group, and butyloxy group.

In an alcoholic hydroxyl group-containing alkyloxyalkyl group, examples of the alkyloxyalkyl group include lower alkyloxy-lower alkyl groups. Specific examples of lower alkyloxy-lower alkyl groups include a methyloxymethyl group, ethyloxymethyl group, propyloxymethyl group, and butyloxymethyl group.

In an alcoholic hydroxyl group-containing alkyl group, examples of the alkyl group include lower alkyl groups. Specific examples of the lower alkyl groups include a methyl group, ethyl group, propyl group, and butyl group.

Here, the description “lower” refers to a number of carbon atoms from 1 to 5.

Furthermore, as the alkali-soluble group, groups in which either a portion of, or all of, the hydrogen atoms of the alkyloxy group, alkyloxyalkyl group, or alkyl group within an aforementioned alcoholic hydroxyl group-containing alkyloxy group, alcoholic hydroxyl group-containing alkyloxyalkyl group, or alcoholic hydroxyl group-containing alkyl group are substituted with fluorine atoms may also be used.

Preferred groups include groups in which a portion of the hydrogen atoms within the alkyloxy group of an alcoholic hydroxyl group-containing alkyloxy group or alcoholic hydroxyl group-containing alkyloxyalkyl group have been substituted with fluorine atoms, and groups in which a portion of the hydrogen atoms within the alkyl group of an alcoholic hydroxyl group-containing alkyl group have been substituted with fluorine atoms, that is, alcoholic hydroxyl group-containing fluoroalkyloxy groups, alcoholic hydroxyl group-containing fluoroalkyloxyalkyl groups, and alcoholic hydroxyl group-containing fluoroalkyl groups.

Examples of the above alcoholic hydroxyl group-containing fluoroalkyloxy groups include a (HO)C(CF₃)₂CH₂O— group, 2-bis(trifluoromethyl)-2-hydroxy-ethyloxy group, (HO)C(CF₃)₂CH₂CH₂O— group and 3-bis(trifluoromethyl)-3-hydroxypropyloxy group.

Examples of the alcoholic hydroxyl group-containing fluoroalkyloxyalkyl groups include a (HO)C(CF₃)₂CH₂O—CH₂— group and a (HO)C(CF₃)₂CH₂CH₂O—CH₂— group.

Examples of the alcoholic hydroxyl group-containing fluoroalkyl groups include a (HO)C(CF₃)₂CH₂— group, 2-bis(trifluoromethyl)-2-hydroxyethyl group, (HO)C(CF₃)₂CH₂CH₂— group and 3-bis(trifluoromethyl)-3-hydroxypropyl group.

Examples of the aforementioned phenolic hydroxyl groups include the phenolic hydroxyl groups contained within novolak resins and poly-(α-methyl)hydroxystyrenes and the like. Of these, because they can be obtained relatively easily and cheaply, the phenolic hydroxyl groups of poly-(α-methyl)hydroxystyrenes are preferred.

Examples of the aforementioned carboxyl groups include the carboxyl groups within structural units derived from ethylenic unsaturated carboxylic acids. Specific examples of such ethylenic unsaturated carboxylic acids include unsaturated carboxylic acids such as acrylic acid, methacrylic acid, maleic acid, and fumaric acid. Of these, acrylic acid and methacrylic acid are particularly preferred as they can be obtained relatively easily and cheaply.

In a portion of the alkali-soluble groups within the component (A), the hydrogen atom is substituted with an acid-dissociable, dissolution-inhibiting group represented by the above general formula (I). In other words, in those cases where the alkali-soluble group is a group that contains a hydroxyl group, such as an alcoholic hydroxyl group, phenolic hydroxyl group, or carboxyl group, the acid-dissociable, dissolution-inhibiting group (I) is bonded to the oxygen atom exposed by removal of the hydrogen atom from that hydroxyl group.

In the general formula (I), R¹ and R² each represent, independently, a hydrogen atom or a lower alkyl group of 1 to 5 carbon atoms. Specific examples of suitable lower alkyl groups for the groups R¹ and R² include straight-chain or branched lower alkyl groups such as a methyl group, ethyl group, propyl group, isopropyl group, n-butyl group, isobutyl group, tert-butyl group, pentyl group, isopentyl group, or neopentyl group. From the viewpoint of industrial availability, the lower alkyl groups are preferably a methyl group or ethyl group.

In terms of achieving superior effects for the present invention, at least one of R¹ and R² is preferably a hydrogen atom, and those cases in which both groups are hydrogen atoms are particularly preferred.

n represents either 0 or an integer from 1 to 3, and preferably represents either 0 or 1.

Z represents an aliphatic cyclic group, and preferably an aliphatic cyclic group of no more than 20 carbon atoms, and even more preferably an aliphatic cyclic group of 5 to 12 carbon atoms. Here, the term “aliphatic” used in the claims and description of the present invention is a relative concept used in relation to the term “aromatic”, and defines a group or compound that contains no aromaticity. The term “aliphatic cyclic group” describes a monocyclic group or polycyclic group that contains no aromaticity. The aliphatic cyclic group may be either saturated or unsaturated, but is usually preferably saturated.

The group Z may either contain, or not contain, substituent groups. Examples of suitable substituent groups include lower alkyl groups of 1 to 5 carbon atoms, a fluorine atom, fluorinated lower alkyl groups of 1 to 5 carbon atoms that have undergone substitution with a fluorine atom, and hydrophilic groups. Examples of hydrophilic groups include ═O, —COOR (wherein R is an alkyl group), alcoholic hydroxyl groups, —OR (wherein R is an alkyl group), imino groups, and amino groups, although from the viewpoint of availability, an ═O group or an alcoholic hydroxyl group is preferred.

The basic ring structure (the base ring) of the aliphatic cyclic group excluding substituent groups may be either a ring formed solely from carbon and hydrogen (a hydrocarbon ring), or a heterocycle in which a portion of the carbon atoms that constitute a hydrocarbon ring are substituted with a hetero atom such as a sulfur atom, oxygen atom, or nitrogen atom. In terms of the effects achieved for the present invention, the base ring within the group Z is preferably a hydrocarbon ring.

This hydrocarbon ring can be appropriately selected from the multitude of compounds proposed for use within KrF resists and ArF resists and the like, and examples include monocycloalkanes, and polycycloalkanes such as bicycloalkanes, tricycloalkanes, and tetracycloalkanes. Specific examples of monocycloalkanes include cyclopentane and cyclohexane. Specific examples of polycycloalkanes include adamantane, norbornane, norbornene, methylnorbornane, ethylnorbornane, methylnorbornene, ethylnorbornene, isobornane, tricyclodecane, and tetracyclododecane. Of these, cyclohexane, cyclopentane, adamantane, norbornane, norbornene, methylnorbornane, ethylnorbornane, methylnorbornene, ethylnorbornene, and tetracyclododecane are preferred industrially, and adamantane is particularly desirable.

Examples of the acid-dissociable, dissolution-inhibiting group (I) include the groups represented by formulas (4) through (15) shown below.

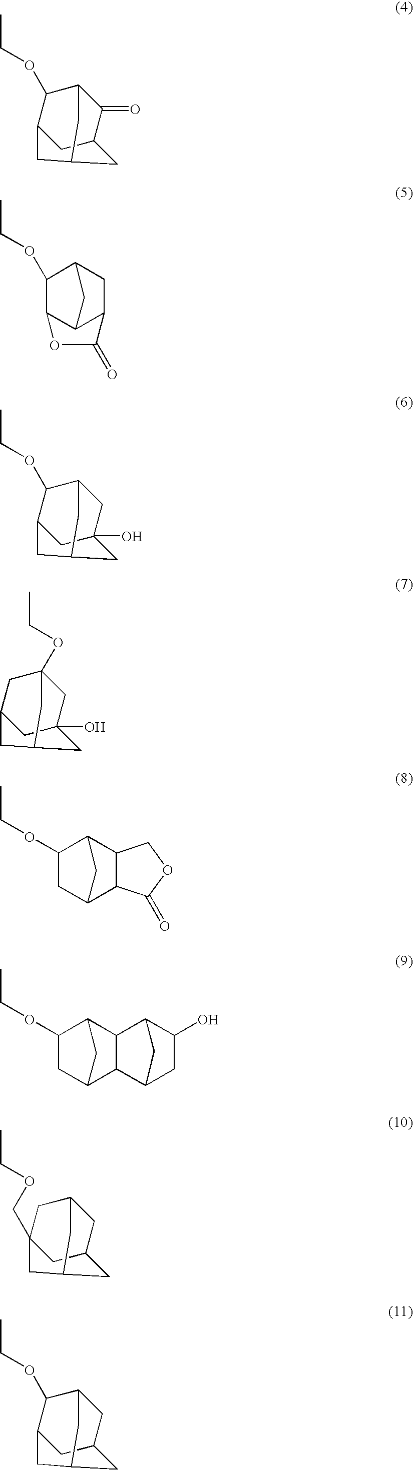

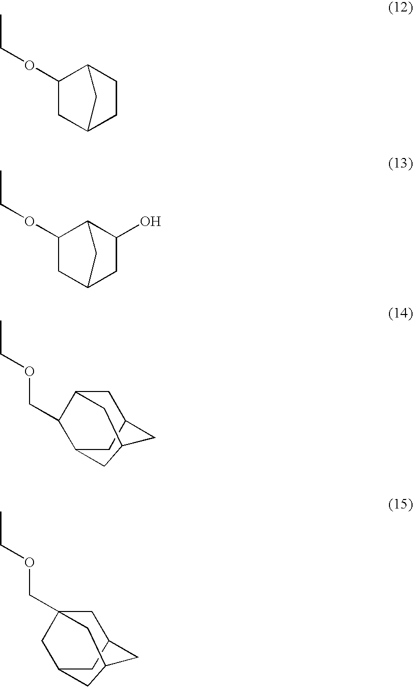

In the resin (A1), there are no particular restrictions on the quantity of the alkali-soluble groups. In order to ensure favorable effects for the present invention, the proportion of structural units having an alkali-soluble group in which the hydrogen atom has been substituted with an acid-dissociable, dissolution-inhibiting group (I), relative to the combined total of all the structural units that constitute the resin (A1), is preferably within a range from 10 to 80 mol %, even more preferably from 20 to 60 mol %, and is most preferably from 25 to 50 mol %.

Furthermore, within the resin (A1), the proportion of alkali-soluble groups in which the hydrogen atom has been substituted with an acid-dissociable, dissolution-inhibiting group (I), relative to the combined total of alkali-soluble groups in which the hydrogen atom has been substituted with an acid-dissociable, dissolution-inhibiting group (I) and alkali-soluble groups in which the hydrogen atom has not been substituted with an acid-dissociable, dissolution-inhibiting group (I) (namely, the protection ratio), is preferably within a range from 10 to 70 mol %, even more preferably from 15 to 60 ml %, and is most preferably from 25 to 50 mol %.

More specific examples of the resin (A1) include resins containing at least one structural unit (hereafter referred to as the structural unit (a1-0)) selected from the group consisting of structural units represented by general formulas (a1-01) and (a1-02) shown below.

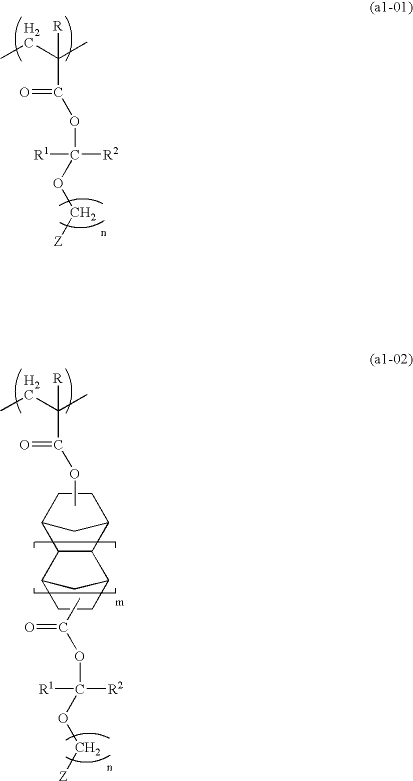

In the above formulas (a1-01) and (a1-02), Z, n, R¹ and R² are as defined above.

m represents either 0 or 1.

Each R group represents, independently, a hydrogen atom, a lower alkyl group of 1 to 5 carbon atoms, a fluorine atom, or a fluorinated lower alkyl group Examples of suitable lower alkyl groups for the group R include the same lower alkyl groups as those listed above in relation to R¹ and R². Furthermore, examples of suitable fluorinated lower alkyl groups for the group R include the lower alkyl groups of R¹ and R² in which a portion of, or all of, the hydrogen atoms are substituted with fluorine atoms

Structural units represented by the formula (a1-01) (hereafter referred to as structural units (a1-01)) and structural units represented by the formula (a1-02) (hereafter referred to as structural units (a1-02)) both represent structural units in which the hydrogen atom of a side-chain terminal carboxyl group is substituted with an acid-dissociable, dissolution-inhibiting group (I).

In the present invention, resins in which the structural units (a1-0) include the structural units (a1-01) exhibit particularly superior effects for the present invention, and are consequently preferred.

More specific examples of the structural unit (a1-0) include the structural units represented by general formulas (a1-01-1) to (a1-01-16), and (a1-02-1) to (a1-02-22) shown below.

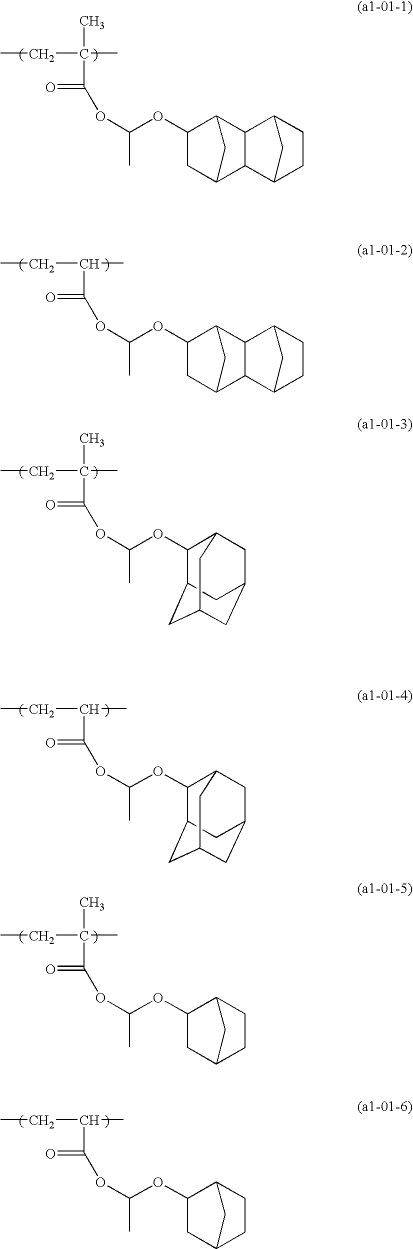

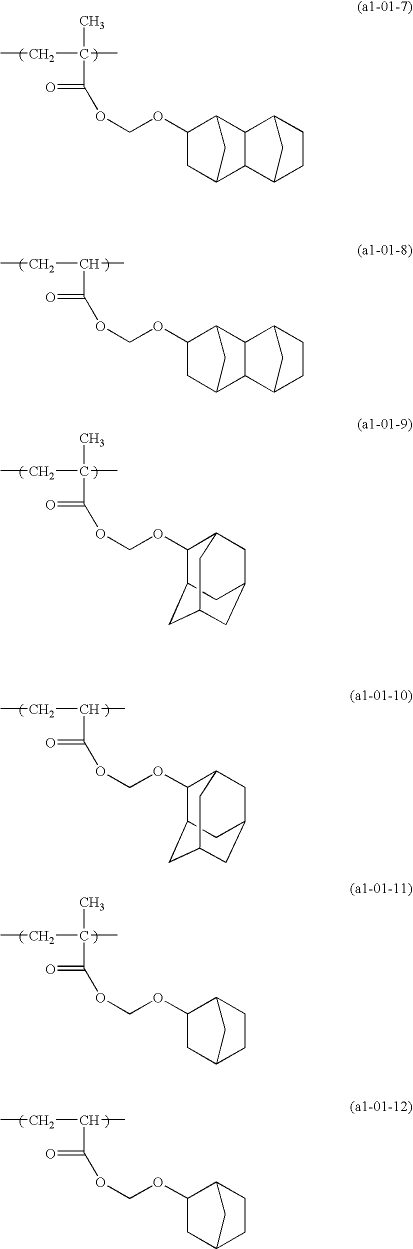

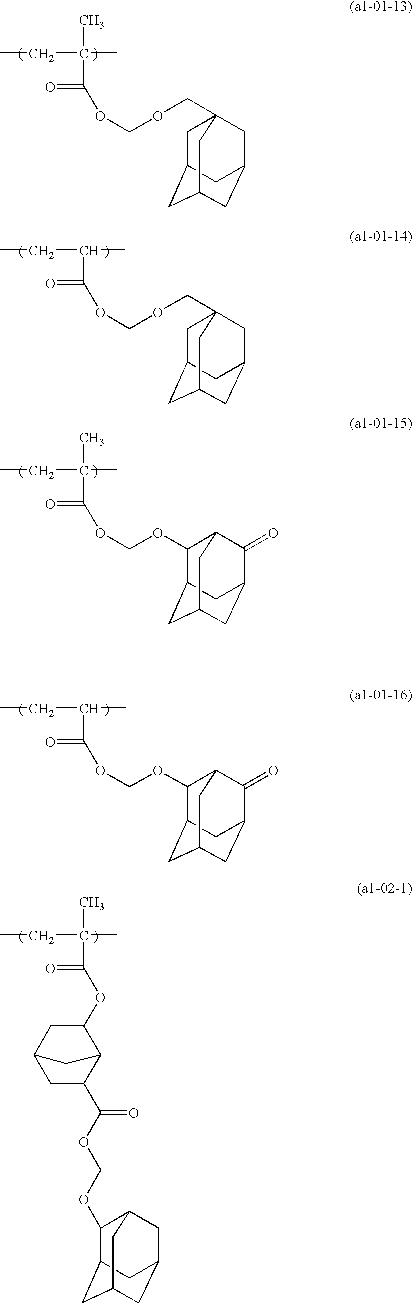

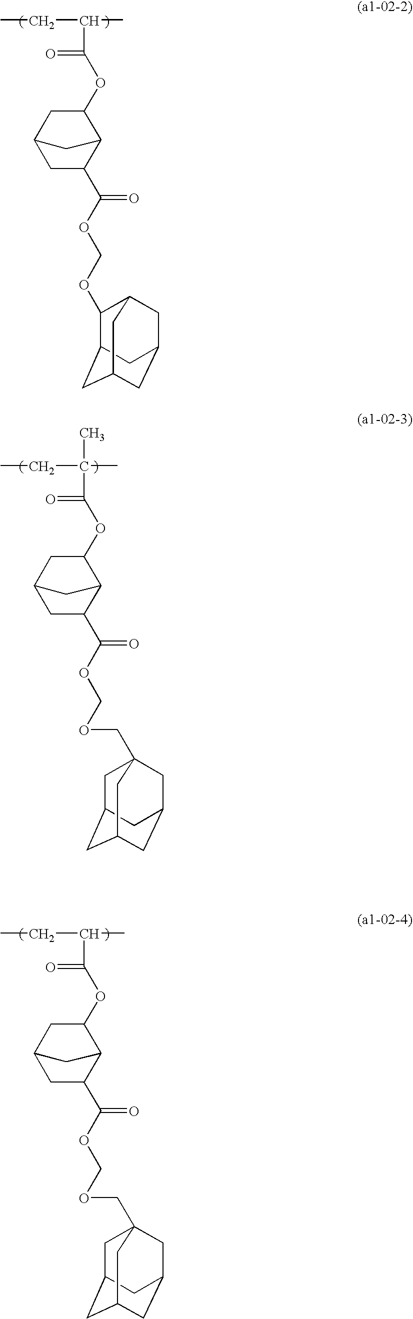

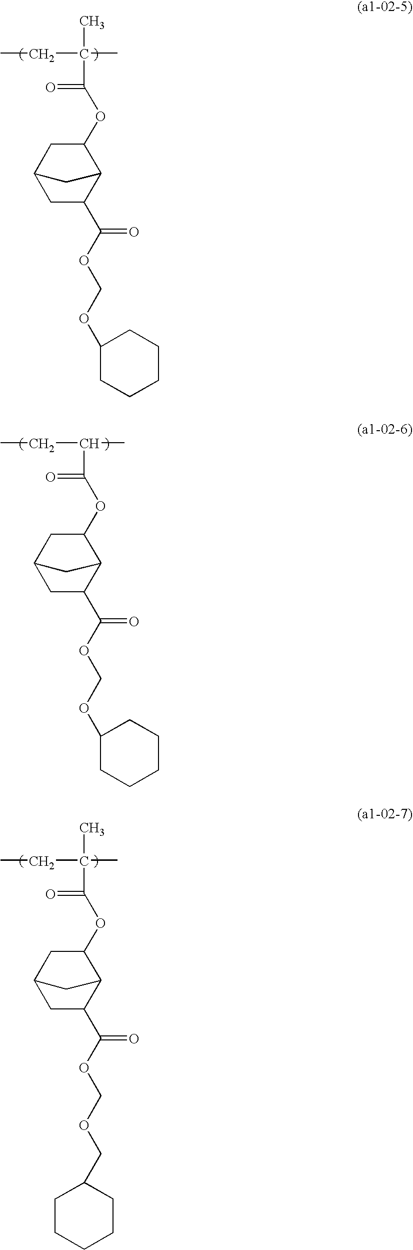

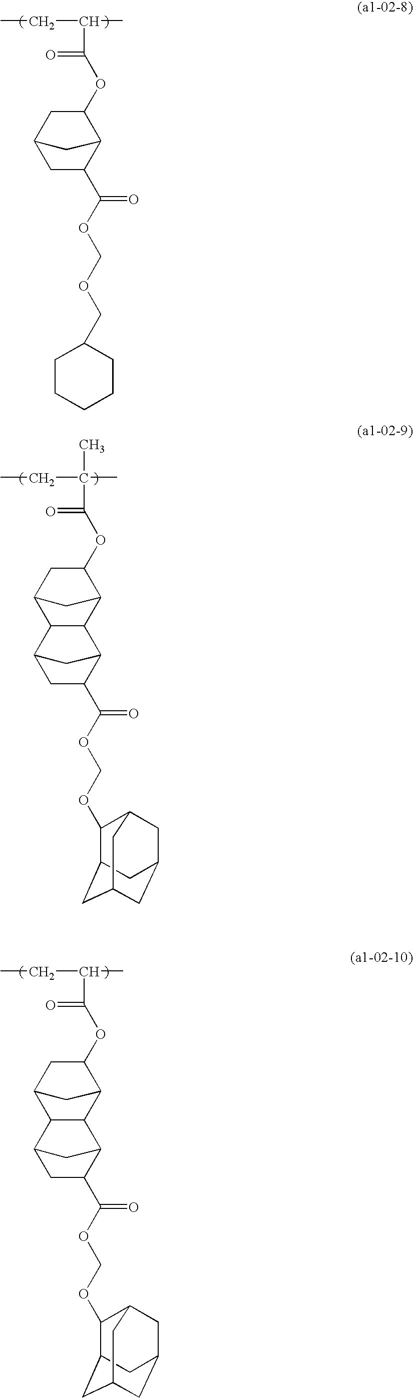

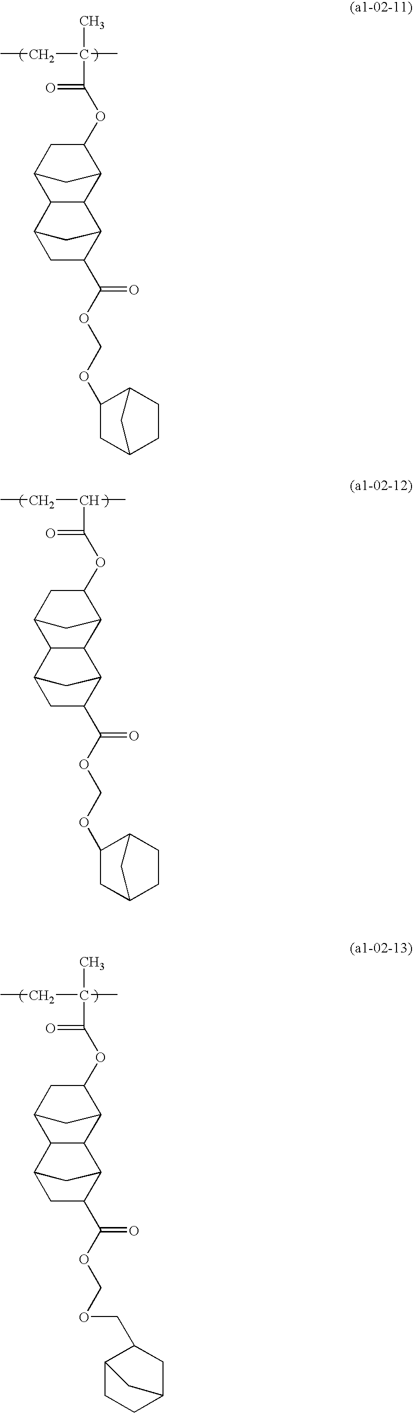

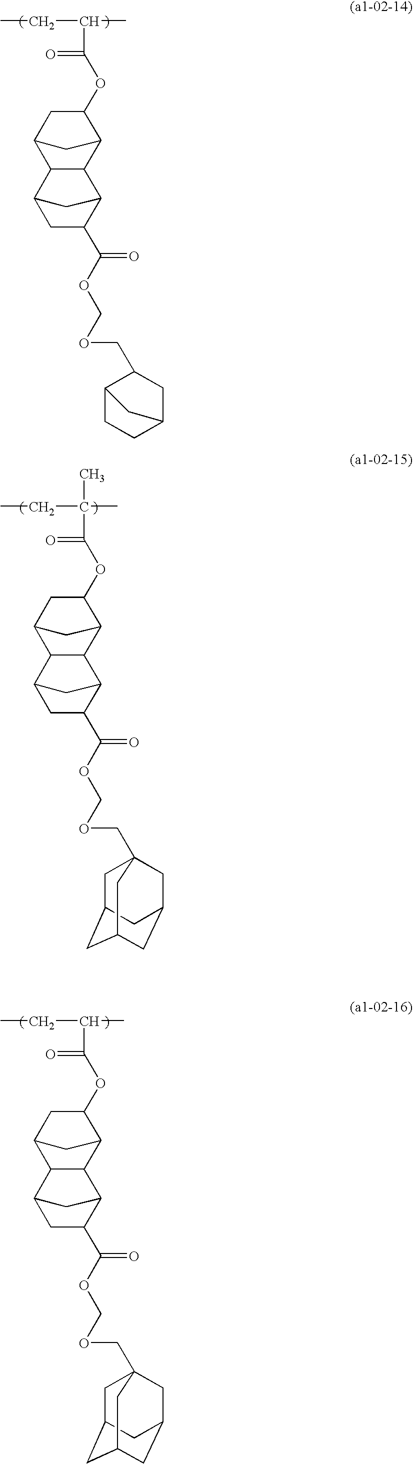

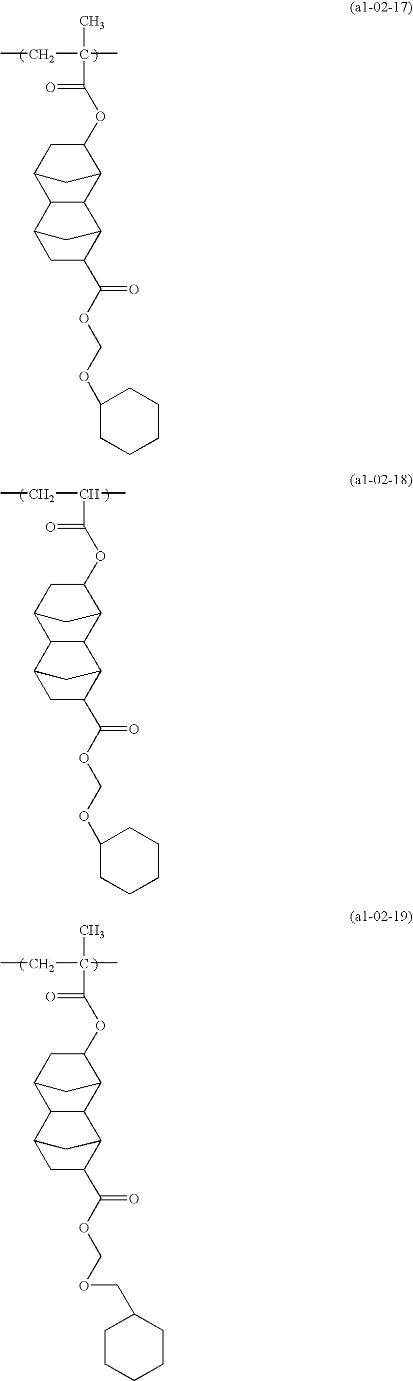

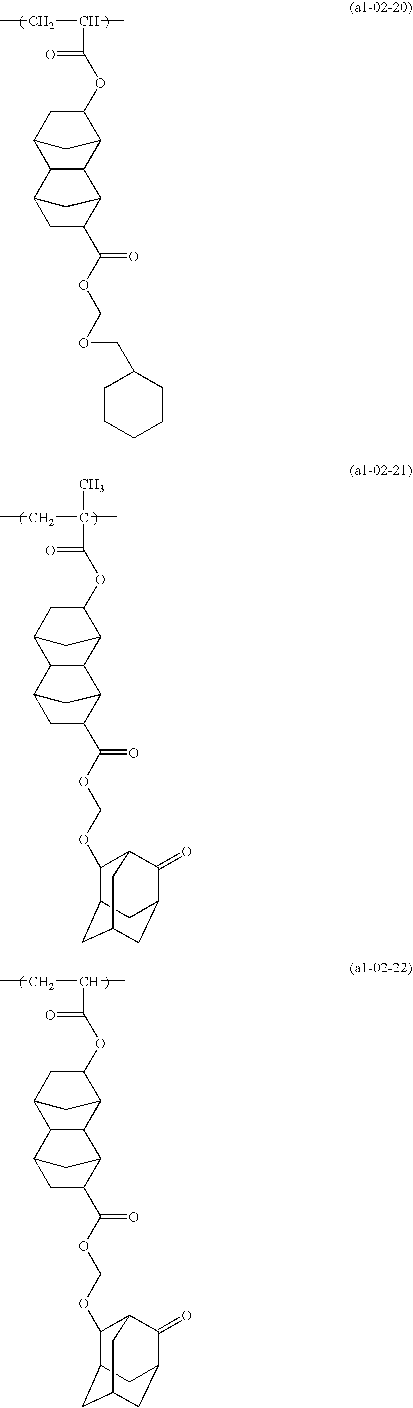

Of these, structural units represented by the formula (a1-01-9), the formula (a1-01-10), the formula (a1-01-13), the formula (a1-0′-14), the formula (a1-01-15), and the formula (a1-01-16) are particularly preferred, as they produce superior results for the present invention.

In the resin (A1), the proportion of the structural unit (a1-0), relative to the combined total of all the structural units that constitute the resin (A1), is preferably within a range from 10 to 80 mol %, even more preferably from 20 to 60 mol %, and is most preferably from 25 to 50 mol %. Ensuring that this proportion is at least as large as the lower limit of this range enables a pattern to be obtained when the resin is used within a resist composition, whereas ensuring that the proportion is no greater than the upper limit enables a more favorable balance to be achieved with the other structural units.

The resin (A1) may also include structural units derived from an (α-lower alkyl)acrylate ester containing an acid-dissociable, dissolution-inhibiting group (hereafter referred to as the acid-dissociable, dissolution-inhibiting group (II)) different from the acid-dissociable, dissolution-inhibiting group (I).

Examples of the lower alkyl group that represents the substituent group at the α-position of the (α-lower alkyl)acrylate ester include the same lower alkyl groups as those described for R in relation to the aforementioned structural unit (a1-0).

As the acid-dissociable, dissolution-inhibiting group (II), any of the groups that have been proposed as acid-dissociable, dissolution-inhibiting groups for the base resins of chemically amplified resists can be used. Generally, groups that form either a cyclic or chain-like tertiary alkyl ester or groups that form a chain-like alkoxyalkyl ester with the carboxyl group of the (meth)acrylate ester are the most widely known. The term “(meth)acrylate ester” is a generic term that includes both the acrylate ester and the methacrylate ester.

Here, a tertiary alkyl ester describes a structure in which an ester is formed by substituting the hydrogen atom of a carboxyl group with an alkyl group or a cycloalkyl group, and a tertiary carbon atom within the alkyl group or cycloalkyl group is bonded to the oxygen atom at the terminal of the carbonyloxy group (—C(O)—O—). In this tertiary alkyl ester, the action of acid causes cleavage of the bond between the oxygen atom and the tertiary carbon atom.

The aforementioned alkyl group or cycloalkyl group may contain a substituent group.

Hereafter, for the sake of simplicity, groups that exhibit acid dissociability as a result of the formation of a tertiary alkyl ester at a carboxyl group are referred to as “tertiary alkyl ester-based acid-dissociable, dissolution-inhibiting groups”.

Furthermore, a chain-like alkoxyalkyl ester describes a structure in which an ester is formed by substituting the hydrogen atom of a carboxyl group with an alkoxyalkyl group, wherein the alkoxyalkyl group is bonded to the oxygen atom at the terminal of the carbonyloxy group (—C(O)—O—). In this alkoxyalkyl ester, the action of acid causes cleavage of the bond between the oxygen atom and the alkoxyalkyl group.

More specific examples of structural units derived from an α-lower alkyl)acrylate ester containing an acid-dissociable, dissolution-inhibiting group (II) include the structural units represented by general formulas (a1-1) to (a1-4) shown below.

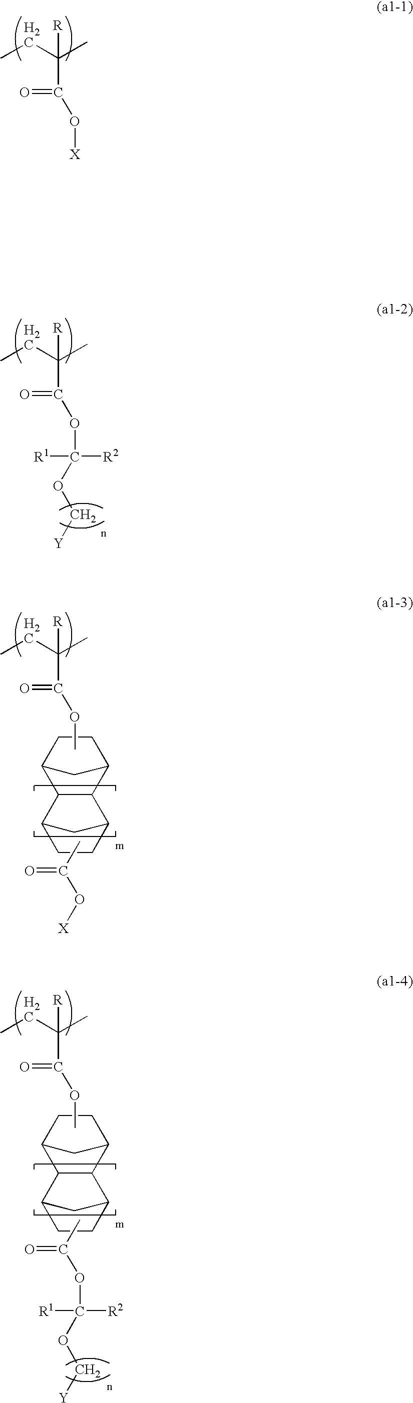

[In the above formulas, X represents a tertiary alkyl ester-based acid-dissociable, dissolution-inhibiting group, Y represents a lower alkyl group of 1 to 5 carbon atoms; n represents either 0 or an integer from 1 to 3; m represents either 0 or 1; and R, R¹ and R² each represent, independently, a hydrogen atom or a lower alkyl group of 1 to 5 carbon atoms.]

At least one of R¹ and R² is preferably a hydrogen atom, and those cases in which both groups are hydrogen atoms are particularly preferred.

n preferably represents either 0 or 1.

X is a tertiary alkyl ester-based acid-dissociable, dissolution-inhibiting group; namely, a group that forms a tertiary alkyl ester with a carboxyl group. Examples include aliphatic branched-chain acid-dissociable, dissolution-inhibiting groups, and acid-dissociable, dissolution-inhibiting groups that contain an aliphatic cyclic group.

For the group X, specific examples of suitable aliphatic branched-chain acid-dissociable, dissolution-inhibiting groups include a tert-butyl group and a tert-amyl group.

For the group X, examples of acid-dissociable, dissolution-inhibiting groups that contain an aliphatic cyclic group include groups that contain a tertiary carbon atom within the ring skeleton of a cycloalkyl group, and specific examples include 2-alkyladamantyl groups such as a 2-methyladamantyl group or 2-ethyladamantyl group. Other possible groups include those that contain an aliphatic cyclic group such as an adamantyl group, and a branched-chain alkylene group that contains a tertiary carbon atom and is bonded to the aliphatic cyclic group, such as the group shown within the structural unit represented by a general formula shown below.

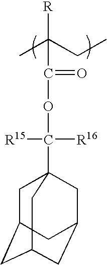

[wherein, R is as defined above, and R¹⁵ and R¹⁶ represent alkyl groups (which may be either straight-chain or branched-chain groups, and preferably contain from 1 to 5 carbon atoms)]

Specific examples of structural units represented by the above general formulas (a1-1) to (a1-4) include those shown below.

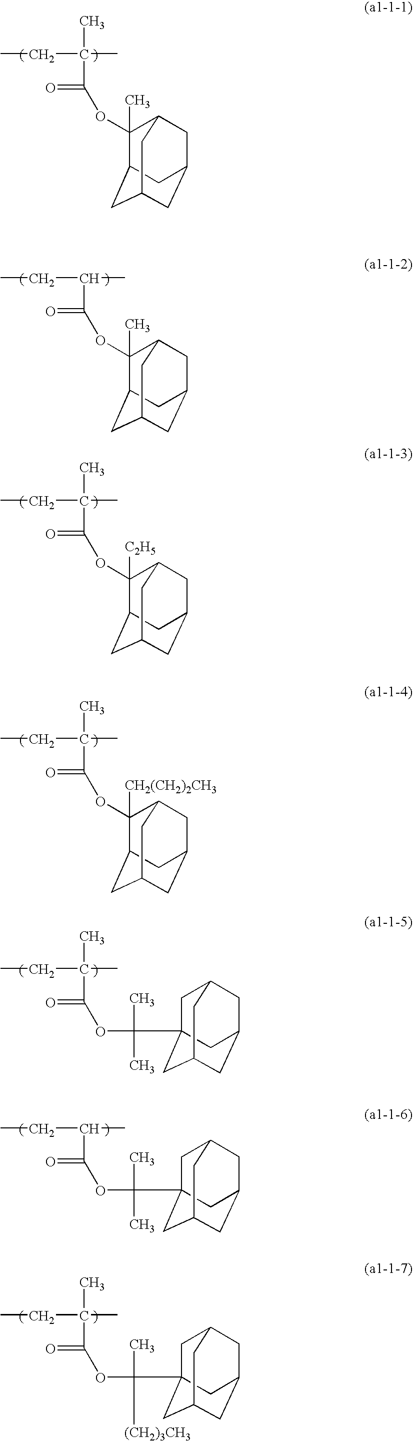

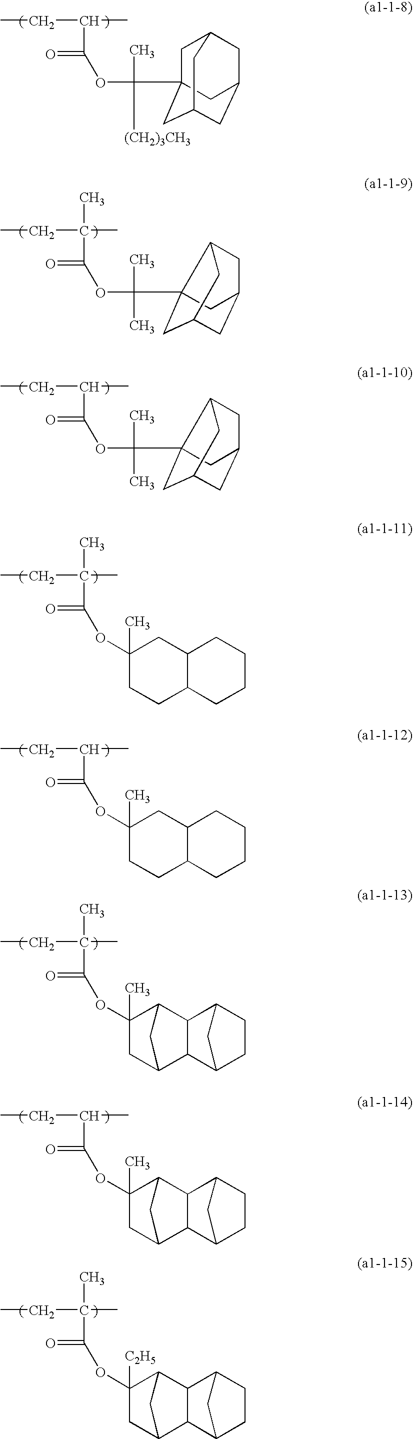

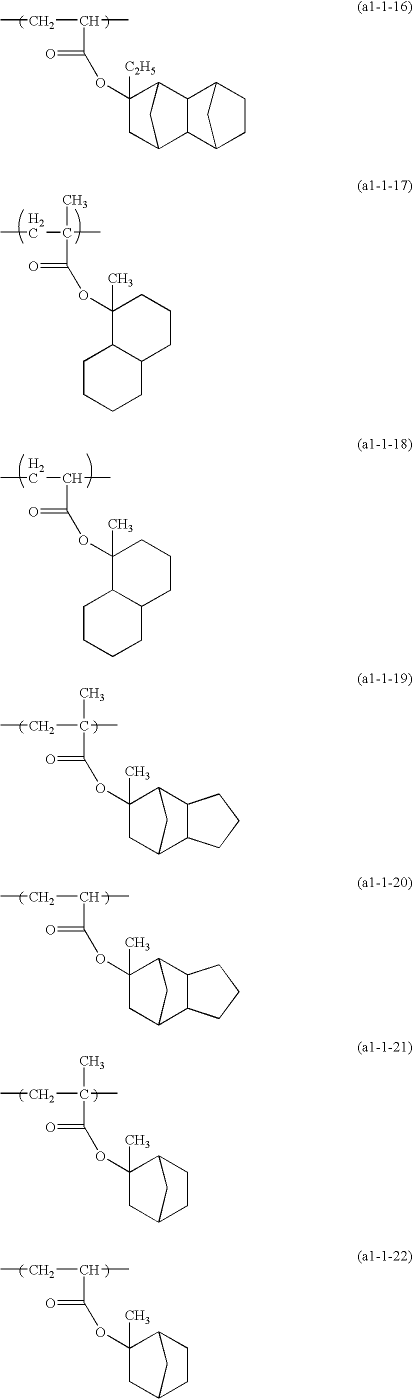

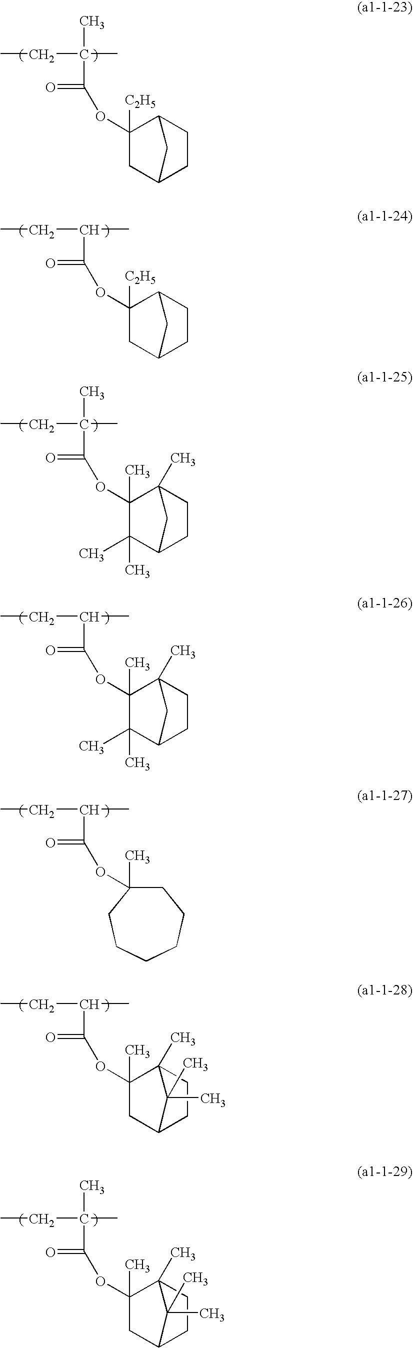

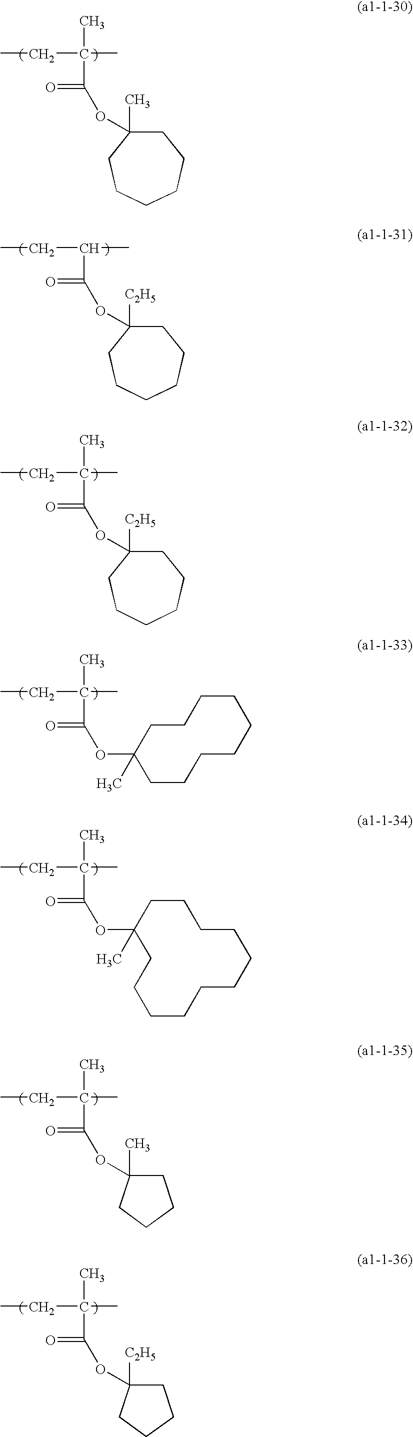

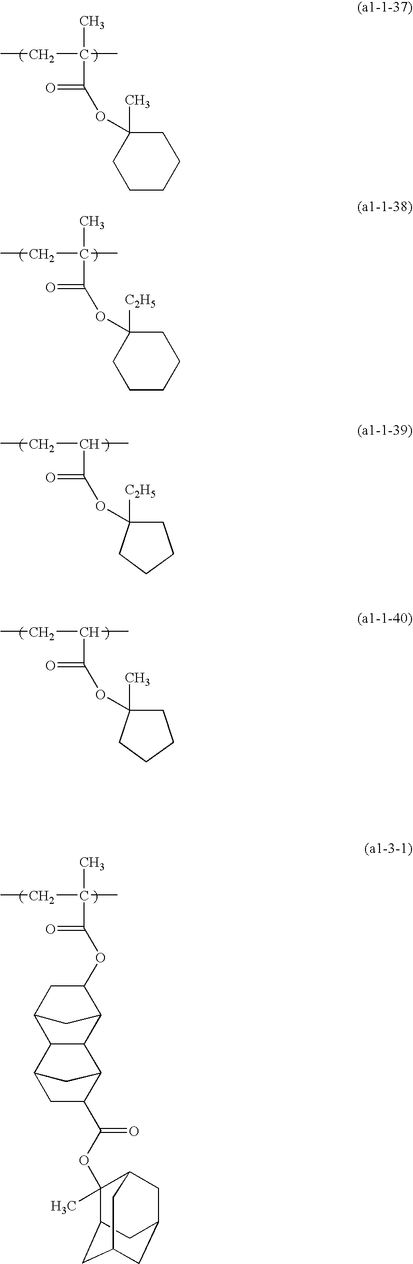

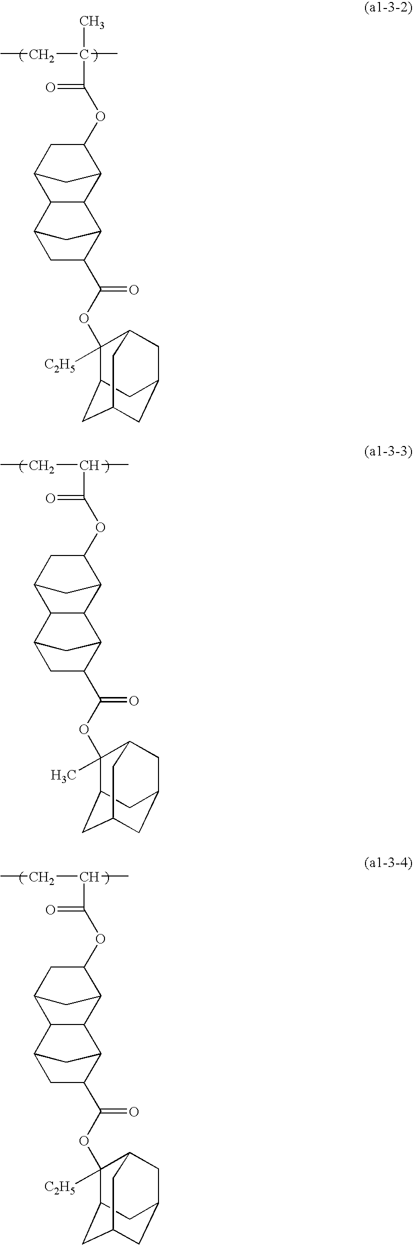

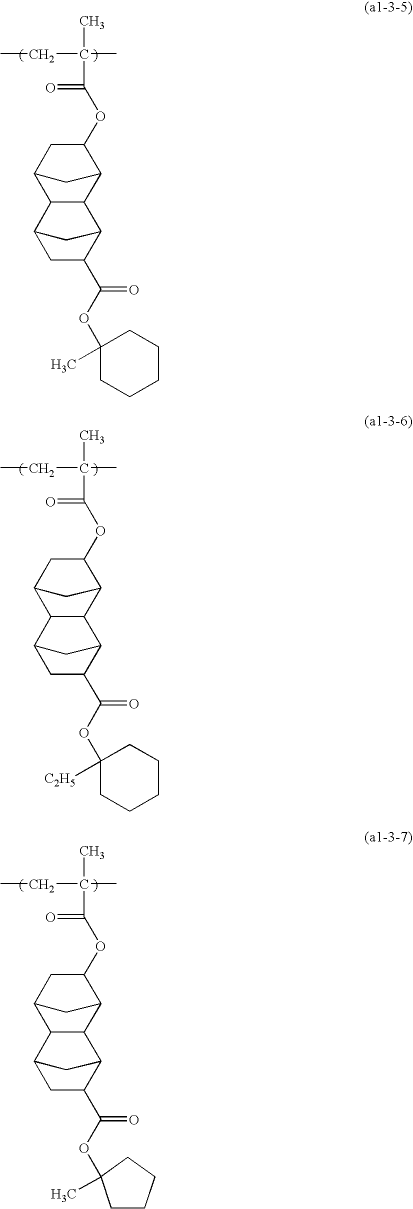

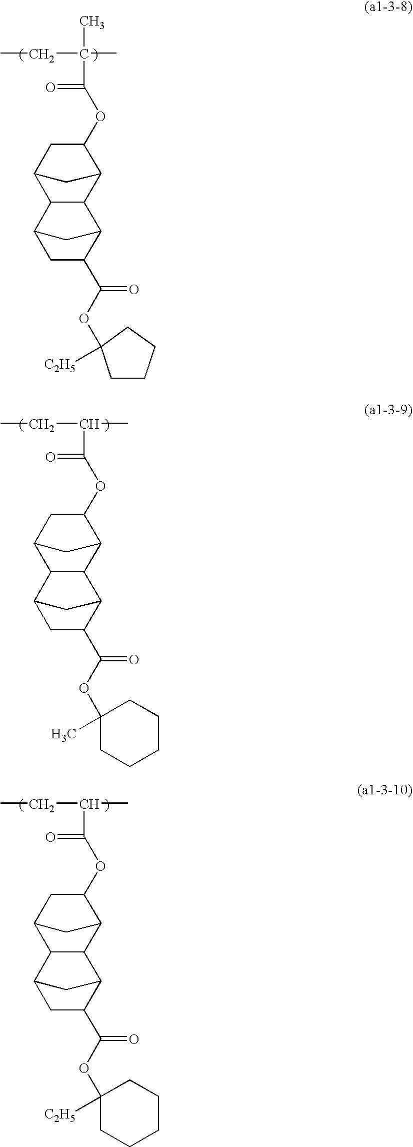

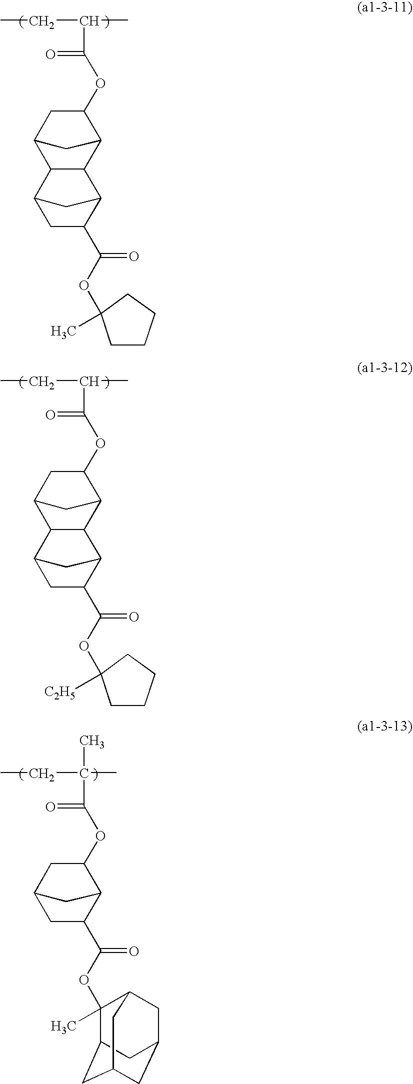

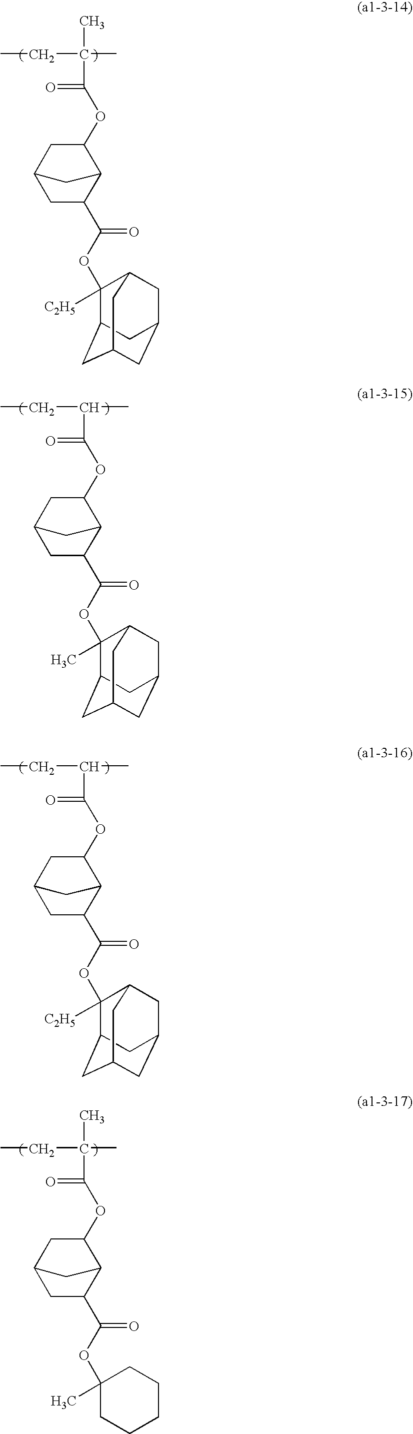

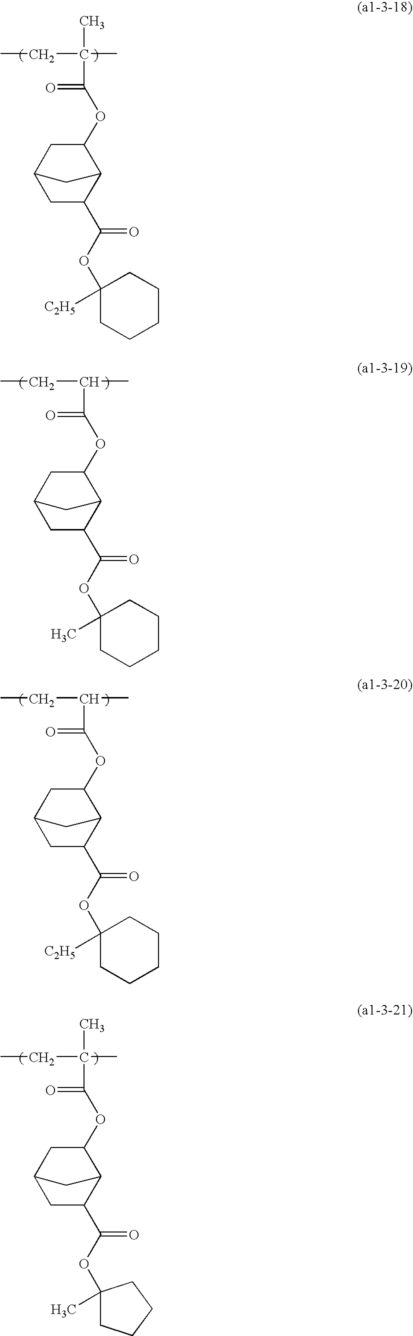

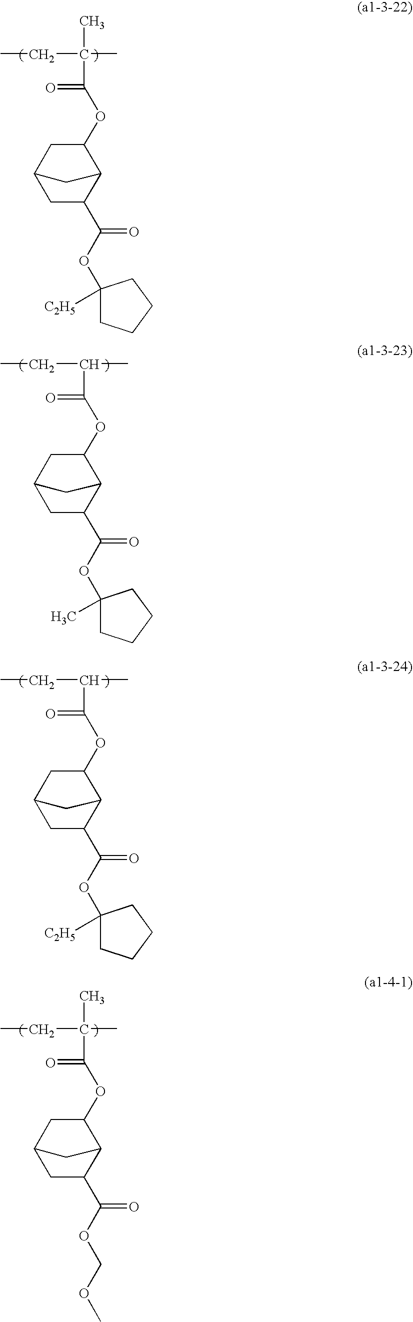

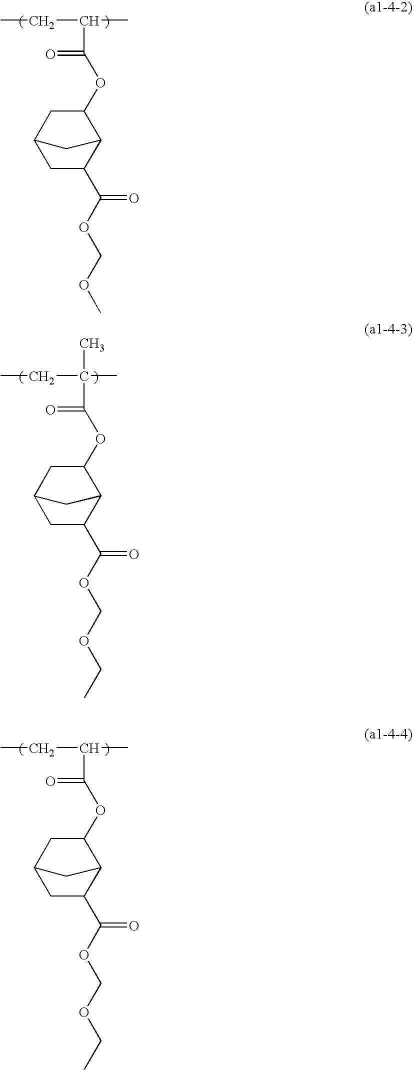

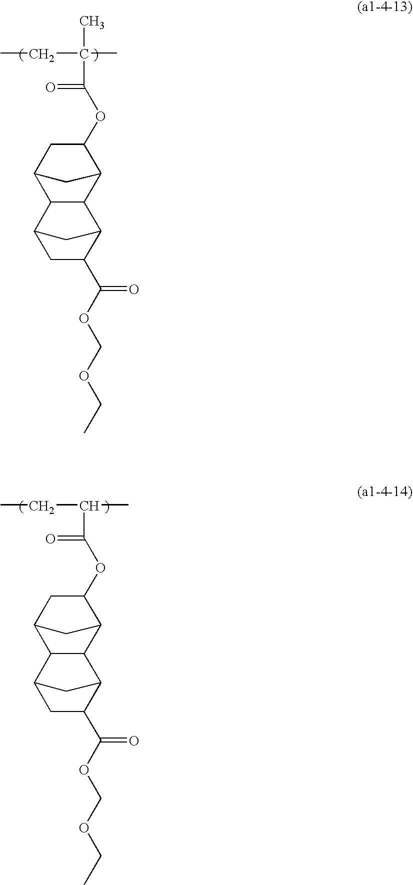

These structural units may be used either alone, or in combinations of two or more different structural units. Of the various possibilities, structural units represented by the general formula (a1-1) are preferred, and more specifically, the use of one or more structural units selected from amongst the structural units represented by the formulas (a1-1-1) to (a1-1-6), and (a1-1-35) to (a1-1-40) is particularly desirable.

In those cases where the resin (A1) includes these structural units, the proportion within the resin (A1) of the combination of structural units represented by the formulas (a1-1) to (a1-4), relative to the combined total of all the structural units that constitute the resin (the polymer compound) (A1), is typically within a range from 10 to 80 mol %, preferably from 20 to 60 mol %, and is most preferably from 25 to 50 mol %.

The resin (A1) preferably also includes a structural unit (a2) derived from an α-lower alkyl)acrylate ester that contains a lactone-containing monocyclic or polycyclic group.

When the resin (A1) is used in forming a resist film, the lactone-containing monocyclic or polycyclic group of the structural unit (a2) is effective in improving the adhesion between the resist film and the substrate, and enhancing the hydrophilicity relative to the developing solution. Furthermore, this type of structural unit also exhibits excellent resistance to dissolution in the solvent used in an immersion exposure step.

Here, a lactone-containing monocyclic or polycyclic group refers to a cyclic group that contains a ring containing a —O—C(O)— structure (namely, a lactone ring). This lactone ring is counted as the first ring, and groups that contain only the lactone ring are referred to as monocyclic groups, whereas groups that also contain other ring structures are described as polycyclic groups regardless of the structure of the other rings.

As the structural unit (a2), any group can be used without any particular restrictions, provided it includes both the above type of lactone structure (—O—C(O)—) and a cyclic group.

Specifically, examples of lactone-containing monocyclic groups include groups in which one hydrogen atom has been removed from γ-butyrolactone. Furthermore, examples of lactone-containing polycyclic groups include groups in which one hydrogen atom has been removed from a lactone ring-containing bicycloalkane, tricycloalkane, or tetracycloalkane. Groups obtained by removing one hydrogen atom from a lactone-containing tricycloalkane with a structural formula such as those shown below are particularly preferred in terms of industrial availability.

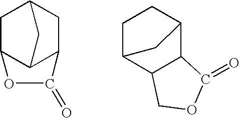

More specific examples of the structural unit (a2) include the structural units represented by general formulas (a2-1) to (a2-5) shown below.

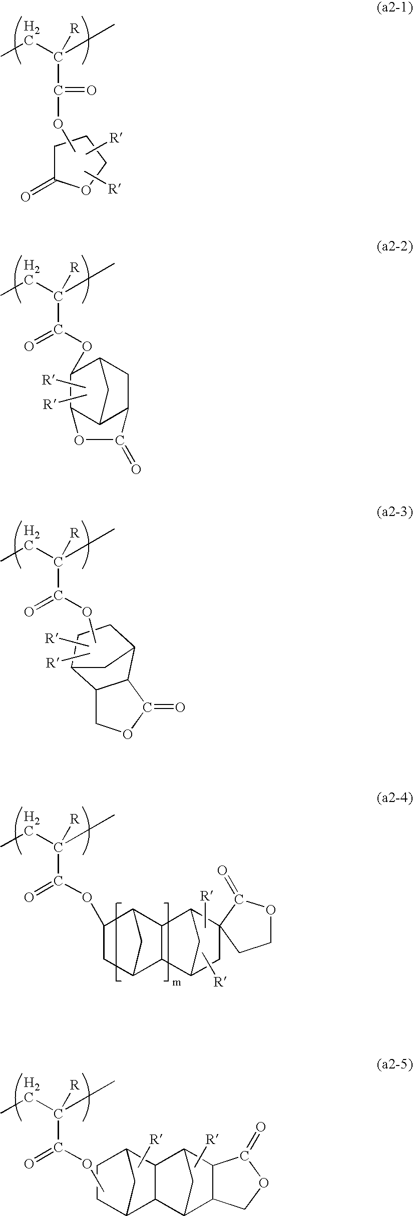

[wherein, R represents a hydrogen atom or a lower alkyl group, R′ represents a hydrogen atom, a lower alkyl group, or an alkoxy group of 1 to 5 carbon atoms, and m represents an integer of 0 or 1]

Examples of the lower alkyl groups of R and R′ within the general formulas (a2-1) to (a2-5) include the same lower alkyl groups as those described in relation to the group R within the structural unit (a1-0).

In the general formulas (a2-1) to (a2-5), considering factors such as industrial availability, R′ is preferably a hydrogen atom.

Specific examples of structural units of the above general formulas (a2-1) to (a2-5) are shown below.

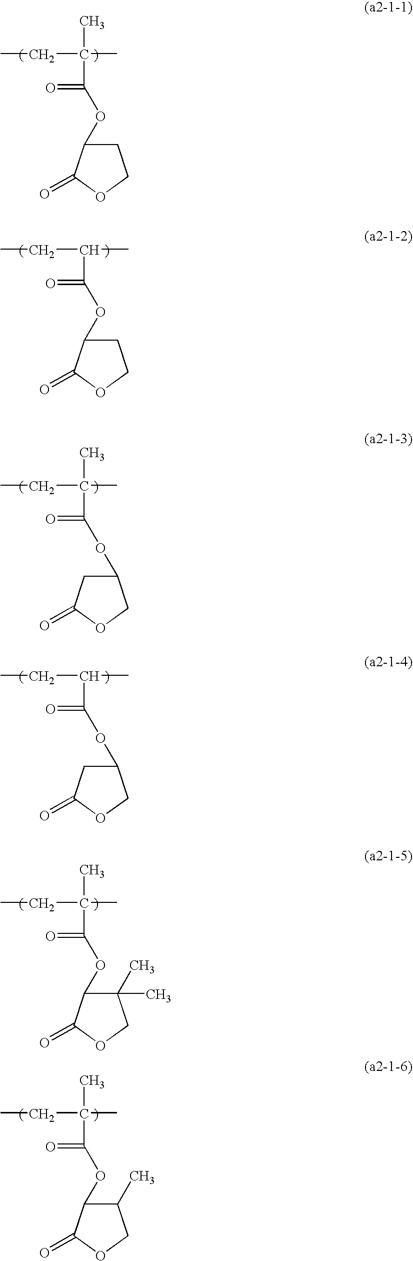

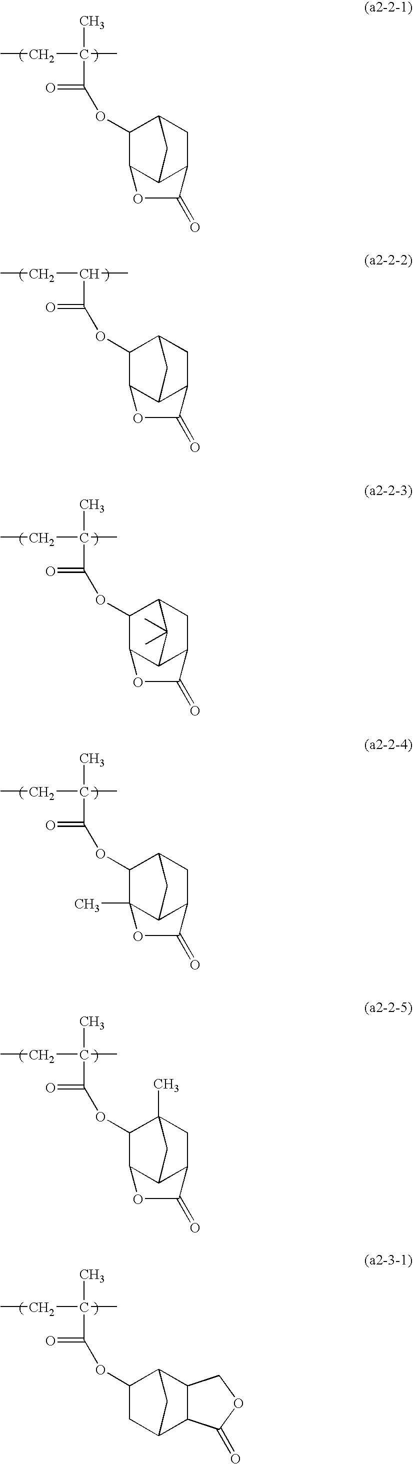

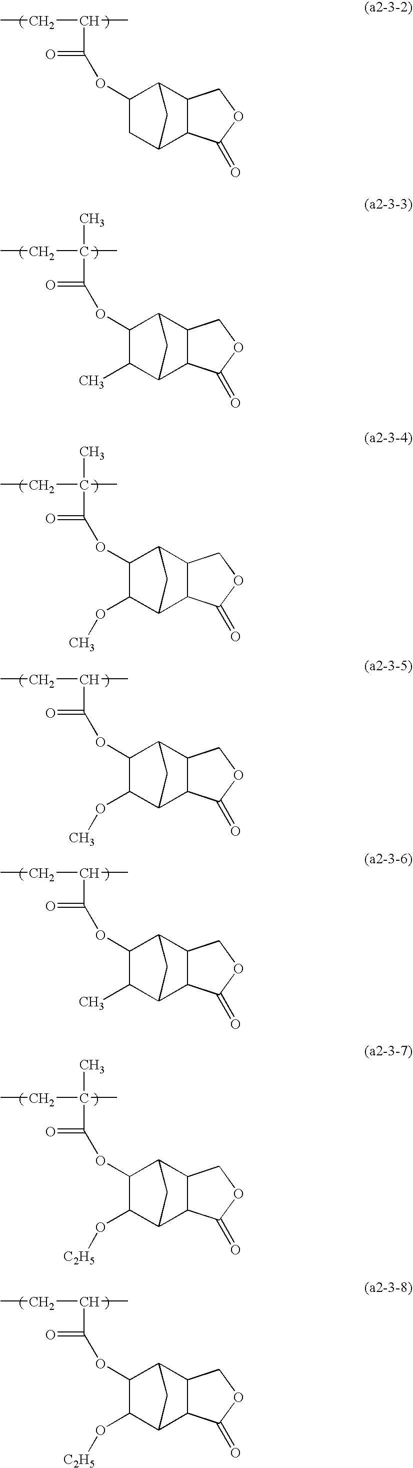

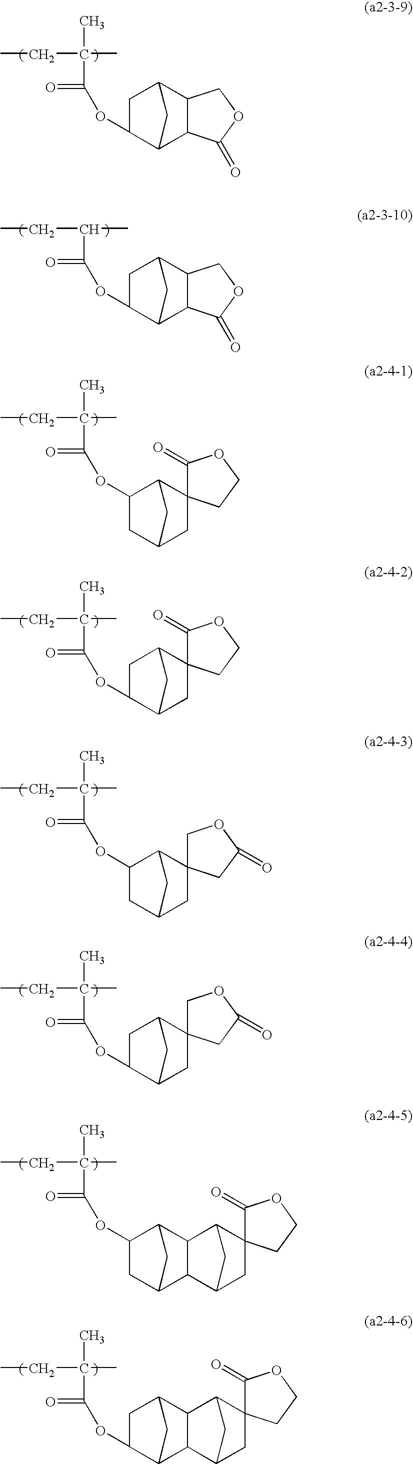

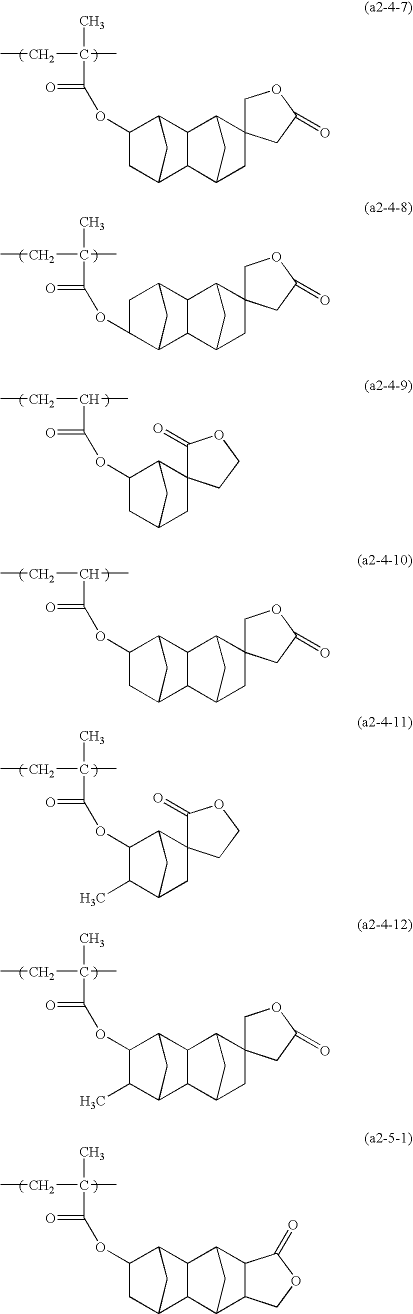

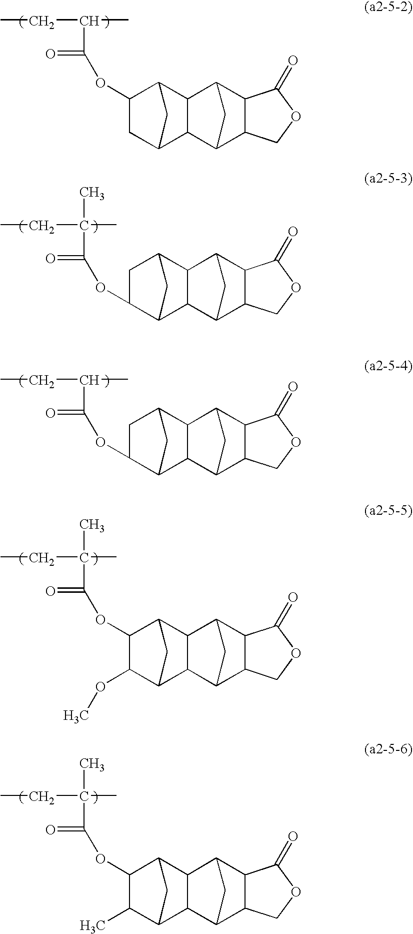

In the general formulas (a2-1) to (a2-5), considering factors such as industrial availability, R′ is preferably a hydrogen atom.

Of the above structural units, the use of at least one structural unit selected from units of the general formulas (a2-1) to (a2-5) is preferred, and the use of at least one structural unit selected from units of the general formulas (a2-1) to (a2-3) is even more desirable. Specifically, the use of at least one structural unit selected from amongst the chemical formulas (a2-1-1), (a2-1-2), (a2-2-1), (a2-2-2), (a2-3-1), (a2-3-2), (a2-3-9), and (a2-3-10) is particularly preferred.

In the resin (A1), as the structural unit (a2), either a single type of structural unit may be used alone, or a combination of two or more different structural units may be used.

The proportion of the structural unit (a2) within the resin (A1), relative to the combined total of all the structural units that constitute the resin (A1), is preferably within a range from 5 to 60 mol %, even more preferably from 10 to 55 mol %, and is most preferably from 25 to 55 mol %. Ensuring that this proportion is at least as large as the lower limit of this range enables the effects obtained by including the structural unit (a2) to be more readily realized, whereas ensuring that the proportion is no greater than the upper limit enables a more favorable balance to be achieved with the other structural units.

In the present invention, the resin (A1) is preferably a copolymer that includes the structural unit (a1-0) and the structural unit (a2) as such copolymers exhibit superior effects for the present invention, and copolymers that include the structural unit (a1-01) and the structural unit (a2) are particularly preferred.

Structural Unit (a3)

The resin (A1) may also include a structural unit (a3) derived from an α-lower alkyl)acrylate ester that contains a polar group-containing aliphatic hydrocarbon group. Including the structural unit (a3) enhances the hydrophilicity of the component (A), thereby improving the affinity with the developing solution, improving the alkali solubility within the exposed portions of the resist, and contributing to an improvement in the resolution. Furthermore, resistance to dissolution in the solvent used in an immersion exposure step is also excellent.

Examples of the polar group include the aforementioned alkali-soluble groups, or a cyano group or the like. A hydroxyl group is particularly preferred.

Examples of the aliphatic hydrocarbon group include straight-chain or branched hydrocarbon groups (and preferably alkylene groups) of 1 to 10 carbon atoms, and polycyclic aliphatic hydrocarbon groups (polycyclic groups). These polycyclic groups can be selected appropriately from the multitude of groups that have been proposed for the resins of resist compositions designed for use with ArF excimer lasers.

Of the various possibilities, structural units that include an aliphatic polycyclic group that contains a hydroxyl group, cyano group, carboxyl group or a hydroxyalkyl group in which a portion of the hydrogen atoms of the alkyl group have been substituted with fluorine atoms, and are also derived from an (α-lower alkyl)acrylate ester are particularly preferred. Examples of suitable polycyclic groups include groups in which one or more hydrogen atoms have been removed from a bicycloalkane, tricycloalkane or tetracycloalkane or the like. Specific examples include groups in which one or more hydrogen atoms have been removed from a polycycloalkane such as adamantane, norbornane, isobornane, tricyclodecane or tetracyclododecane. These types of polycyclic groups can be selected appropriately from the multitude of groups proposed for the polymer (resin component) of resist compositions designed for use with ArF excimer lasers. Of these polycyclic groups, groups in which two or more hydrogen atoms have been removed from adamantane, groups in which two or more hydrogen atoms have been removed from norbornane, and groups in which two or more hydrogen atoms have been removed from tetracyclododecane are preferred industrially.

When the hydrocarbon group within the polar group-containing aliphatic hydrocarbon group is a straight-chain or branched hydrocarbon group of 1 to 10 carbon atoms, the structural unit (a3) is preferably a structural unit derived from the hydroxyethyl ester of the (α-lower alkyl)acrylic acid, whereas when the hydrocarbon group is a polycyclic group, examples of preferred structural units include the structural units represented by a formula (a3-1), the structural units represented by a formula (a3-2), and the structural units represented by a formula (a3-3), all of which are shown below.

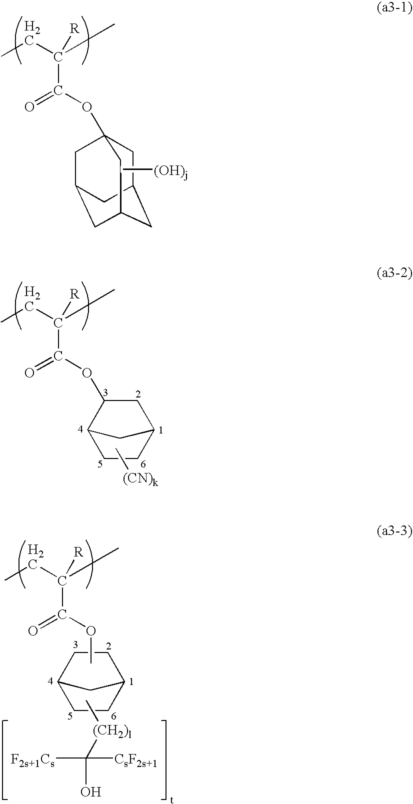

(wherein, R is as defined above, j represents an integer from 1 to 3, k represents an integer from 1 to 3, t represents an integer from 1 to 3, l represents an integer from 1 to 5, and s represents an integer from 1 to 3)

In the formula (a3-1), the value of j is preferably either 1 or 2, and is most preferably 1. In those cases where j is 2, the hydroxyl groups are preferably bonded to position 3 and position 5 of the adamantyl group. In those cases where j is 1, the hydroxyl group is preferably bonded to position 3 of the adamantyl group. The value of j is preferably 1, and the hydroxyl group particularly preferably bonded to position 3 of the adamantyl group.

In the formula (a3-2), the value of k is preferably 1. The cyano group is preferably bonded to either position 5 or position 6 of the norbornyl group.

In the formula (a3-3), the value of t is preferably 1. The value of 1 is also preferably 1. The value of s is also preferably 1. In these units, a 2-norbornyl group or 3-norbornyl group is preferably bonded to the carboxyl group terminal of the (α-lower alkyl)acrylic acid. A fluorinated alkyl alcohol is preferably bonded to either position 5 or 6 of the norbornyl group.

As the structural unit (a3), either a single type of structural unit may be used alone, or a combination of two or more different structural units may be used.

In those cases where the resin (A1) includes a structural unit (a3), the proportion of the structural unit (a3) within the resin (A1), relative to the combined total of all the structural units that constitute the resin (A1), is preferably within a range from 5 to 50 mol %, and even more preferably from 10 to 35 mol %.

Structural Unit (a4)

The resin (A1) may also include other structural units (a4) besides the structural units described above, provided the inclusion of these other units does not impair the effects of the present invention.

As the structural unit (a4), any other structural unit that cannot be classified as one of the above structural units can be used without any particular restrictions, and any of the multitude of conventional structural units used within resist resins for ArF excimer lasers or KrF excimer lasers (and particularly for ArF excimer lasers) can be used.

As the structural unit (a4), a structural unit that contains a non-acid-dissociable aliphatic polycyclic group, and is also derived from an (α-lower alkyl)acrylate ester is preferred. Examples of this polycyclic group include the same groups as those described above in relation to the aforementioned structural unit (a3), and any of the multitude of conventional polycyclic groups used within the resin component of resist compositions for ArF excimer lasers or KrF excimer lasers (and particularly for ArF excimer lasers) can be used.

In particular, at least one group selected from amongst a tricyclodecanyl group, adamantyl group, tetracyclododecanyl group, isobornyl group, and norbornyl group is preferred in terms of factors such as industrial availability. The polycyclic groups may also be substituted with a straight-chain or branched alkyl group of 1 to 5 carbon atoms.

Specific examples of the structural unit (a4) include units with structures represented by general formulas (a4-1) to (a4-5) shown below.

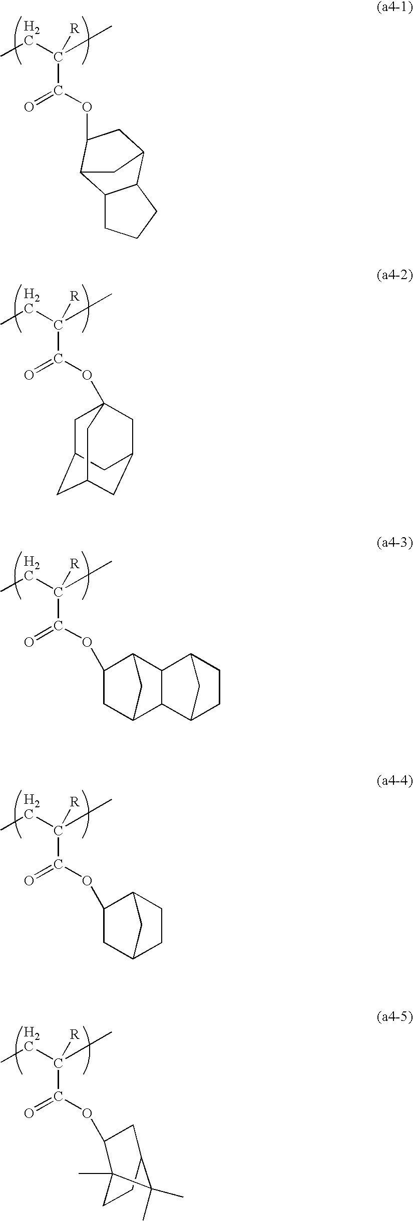

(wherein, R is as defined above)

Although the structural unit (a4) is not an essential component of the resin (A1), if included within the resin (A1), the proportion of the structural unit (a4), relative to the combined total of all the structural units that constitute the resin (A1), is typically within a range from 1 to 30 mol %, and is preferably from 10 to 20 mol %.

The resin (A1) can be synthesized using known methods, including polymerization methods that employ a conventional radical polymerization or the like of the monomers corresponding with each of the structural units, using a radical polymerization initiator such as azobisisobutyronitrile (AIBN), and the methods disclosed in the above non-patent references.

More specifically, the resin (A1) can be produced, for example, by substituting the hydrogen atoms of alkali-soluble groups within a resin having alkali-soluble groups (a precursor), and introducing the acid-dissociable, dissolution-inhibiting groups (I). In an example of a specific method, a halogenated methyl ether compound is synthesized using an alcohol compound containing a halogen atom such as a chlorine or bromine atom, and this halogenated methyl ether compound is then reacted with the alkali-soluble groups of the precursor, which enables introduction of the acid-dissociable, dissolution-inhibiting groups (I). For example, using a chloromethyl ether compound as a starting material, and reacting this compound with the alkali-soluble groups of the precursor, which are selected from amongst alcoholic hydroxyl groups, carboxyl groups, and phenolic hydroxyl groups, the alkali-soluble groups can be protected with the acid-dissociable, dissolution-inhibiting groups (I).

The above chloromethyl ether compound can be synthesized using a known method such as that represented by the reaction formula shown below. In other words, paraformaldehyde is added to an alcohol compound, and a reaction is then conducted at 40 to 100° C. by blowing a 2.0 to 3.0 equivalence of hydrogen chloride gas through the alcohol compound in the presence of hydrochloric acid. Following completion of the reaction, the target chloromethyl ether compound can be obtained by distillation of the reaction product under reduced pressure. In the reaction formula shown below, R corresponds with the group represented by —(CH₂)ₙ-Z in the target compound.

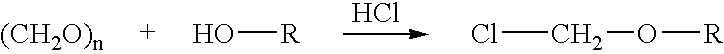

Examples of the above chloromethyl ether compound include, for example, 4-oxo-2-adamantyl chloromethyl ether represented by the chemical formula (36) shown below, 2-adamantyl chloromethyl ether represented by the chemical formula (37) shown below, and 1-adamantylmethyl chloromethyl ether represented by the chemical formula (38) shown below.

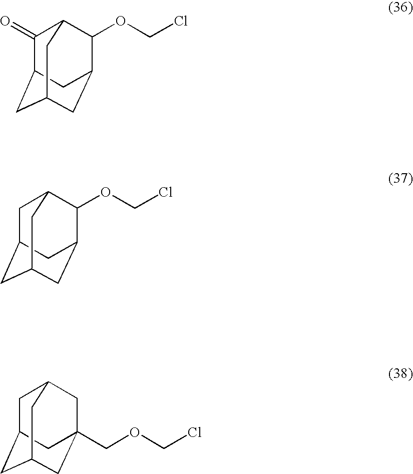

Furthermore, —C(CF₃)₂—OH groups may be introduced at the terminals of the resin (A1) by also using a chain transfer agent such as HS—CH₂—CH₂—CH₂—C(CF₃)₂—OH during the above polymerization. A copolymer wherein hydroxyalkyl groups, in which a portion of the hydrogen atoms of the alkyl group have been substituted with fluorine atoms, have been introduced in this manner is effective in reducing the levels of developing defects and LER (line edge roughness: non-uniform irregularities within the line side walls).

Although there are no particular restrictions on the weight average molecular weight (Mw) (the polystyrene equivalent value determined by gel permeation chromatography) of the resin (A1), the molecular weight value is preferably within a range from 2,000 to 50,000, even more preferably from 3,000 to 30,000, and is most preferably from 5,000 to 20,000. Provided the molecular weight is lower than the upper limit of this range, the level of solubility within resist solvents is adequate for use within a resist, whereas provided the molecular weight is larger than the lower limit of the above range, favorable levels of dry etching resistance and a favorable cross-sectional shape for the resist pattern can be obtained.

Furthermore, the polydispersity (Mw/Mn) is preferably within a range from 1.0 to 5.0, and even more preferably from 1.0 to 3.0.

The resin (A1) may be used either alone, or in combinations of two or more different resins.

In order to maximize the effects of the present invention, the proportion of the resin (A1) within the component (A) is preferably at least 50% by weight, is even more preferably within a range from 80 to 100% by weight, and is most preferably 100% by weight.

In the present invention, the component (A) may also include, in addition to the resin (the polymer compound) (A1), the types of resins typically used as chemically amplified positive resist resins. Such resins do not contain the acid-dissociable, dissolution-inhibiting groups (I) of the resin (A1), but may include structural units that contain an acid-dissociable, dissolution-inhibiting group other than the acid-dissociable, dissolution-inhibiting group (I), and examples include resins (hereafter referred to as resins (A2)) that do not contain the aforementioned structural unit (a1-0), but do contain one of the above structural units (a1-1) to (a1-4) (hereafter, these structural units may be referred to jointly as the structural unit (a1′)), and may also optionally include one or more structural units selected from amongst the above structural units (a2) to (a4).

As this resin (A2), one or more resins selected appropriately from known resin components used within conventional chemically amplified positive resist compositions can be used.

More specific examples of the resin (A2) include resins (hereafter referred to as resins (A2-1)) containing the aforementioned structural units (a1′), (a2) and/or (a3).

In the resin (A2-1), the proportion of the structural unit (a1′), relative to the combined total of all the structural units that constitute the resin (A2-1), is typically within a range from 5 to 80 mol %, and preferably from 10 to 70 mol %. Furthermore, the proportion of the structural unit (a2), relative to the combined total of all the structural units that constitute the resin (A2-1), is typically within a range from 5 to 50 mol %, and preferably from 10 to 40 mol %. Furthermore, the proportion of the structural unit (a3), relative to the combined total of all the structural units that constitute the resin (A2-1), is typically within a range from 5 to 80 mol %, and preferably from 10 to 60 mol %.

The resin (A2-1) may also include an aforementioned structural unit (a4).

The weight average molecular weight of the resin (A2-1) is preferably within a range from 5,000 to 30,000, and is even more preferably from 6,000 to 20,000. Furthermore, the polydispersity (Mw/Mn) is preferably within a range from 1.0 to 5.0, and is even more preferably from 1.0 to 3.0.

The proportion of the component (A) within the positive resist composition can be adjusted appropriately in accordance with the desired resist film thickness.

### <Component (B)>

There are no particular restrictions on the component (B), and any of the compounds proposed as acid generators proposed for conventional chemically amplified positive resists can be used. Examples of these acid generators are numerous, and include onium salt-based acid generators such as iodonium salts and sulfonium salts, oxime sulfonate-based acid generators, diazomethane-based acid generators such as bisalkyl or bisaryl sulfonyl diazomethanes and poly(bis-sulfonyl)diazomethanes, nitrobenzyl sulfonate-based acid generators, iminosulfonate-based acid generators, and disulfone-based acid generators.

Specific examples of suitable onium salt-based acid generators include diphenyliodonium trifluoromethanesulfonate or nonafluorobutanesulfonate, bis(4-tert-butylphenyl)iodonium trifluoromethanesulfonate or nonafluorobutanesulfonate, triphenylsulfonium trifluoromethanesulfonate, heptafluoropropanesulfonate or nonafluorobutanesulfonate, tri(4-methylphenyl)sulfonium trifluoromethanesulfonate, heptafluoropropanesulfonate or nonafluorobutanesulfonate, dimethyl(4-hydroxynaphthyl)sulfonium trifluoromethanesulfonate, heptafluoropropanesulfonate or nonafluorobutanesulfonate, monophenyldimethylsulfonium trifluoromethanesulfonate, heptafluoropropanesulfonate or nonafluorobutanesulfonate, diphenylmonomethylsulfonium trifluoromethanesulfonate, heptafluoropropanesulfonate or nonafluorobutanesulfonate, (4-methylphenyl)diphenylsulfonium trifluoromethanesulfonate, heptafluoropropanesulfonate or nonafluorobutanesulfonate, 4-methoxyphenyl)diphenylsulfonium trifluoromethanesulfonate, heptafluoropropanesulfonate or nonafluorobutanesulfonate, and tri(4-tert-butyl)phenylsulfonium trifluoromethanesulfonate, heptafluoropropanesulfonate or nonafluorobutanesulfonate.

Specific examples of suitable oxime sulfonate-based acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)-benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-α-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile. Of these, α-(methylsulfonyloxyimino)-p-methoxyphenyl acetonitrile is preferred.

Furthermore, oxime sulfonate-based acid generators represented by the chemical formulas shown below can also be used.

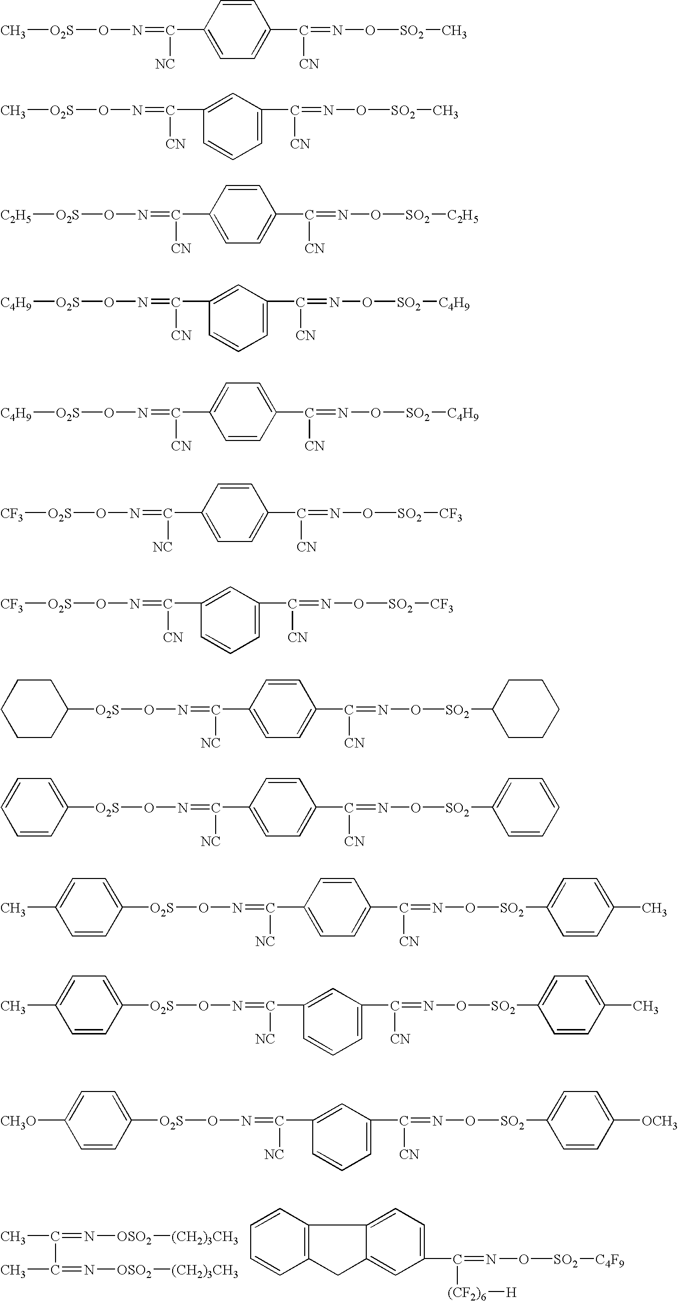

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Furthermore, specific examples of poly(bis-sulfonyl)diazomethanes include the structures shown below, such as 1,3-bis(phenylsulfonyldiazomethylsulfonyl)propane (compound A, decomposition point 135° C.), 1,4-bis(phenylsulfonyldiazomethylsulfonyl)butane (compound B, decomposition point 147° C.), 1,6-bis(phenylsulfonyldiazomethylsulfonyl)hexane (compound C, melting point 132° C., decomposition point 145° C.), 1,10-bis(phenylsulfonyldiazomethylsulfonyl)decane (compound D, decomposition point 147° C.), 1,2-bis(cyclohexylsulfonyldiazomethylsulfonyl)ethane (compound E, decomposition point 149° C.), 1,3-bis(cyclohexylsulfonyldiazomethylsulfonyl)propane (compound F, decomposition point 153° C.), 1,6-bis(cyclohexylsulfonyldiazomethylsulfonyl)hexane (compound G, melting point 109° C., decomposition point 122° C.), and 1,10-bis(cyclohexylsulfonyldiazomethylsulfonyl)decane (compound H, decomposition point 116° C.).

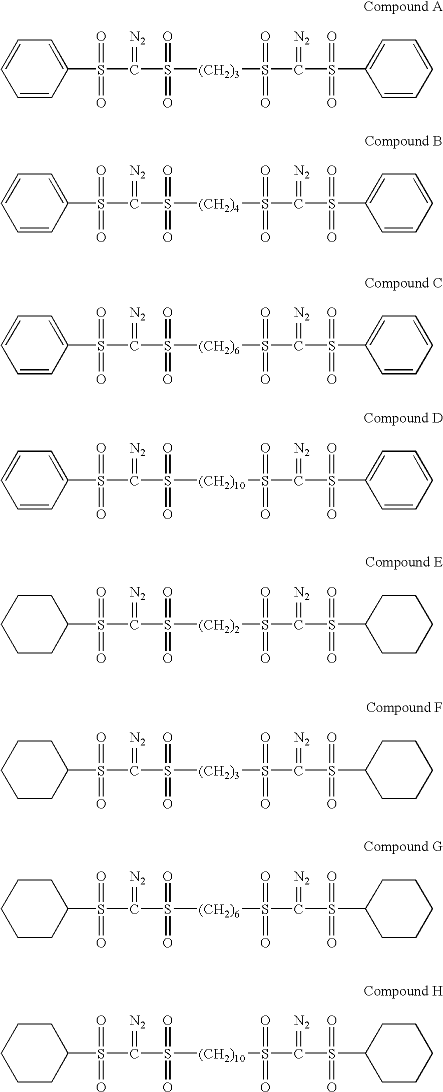

In the present invention, of the various possibilities, the component (B) preferably uses an onium salt containing a fluorinated alkylsulfonate ion as the anion.

Furthermore, in the present invention, a satisfactory resist pattern can still be formed even if a non-ionic acid generator such as an oxime sulfonate-based acid generator or diazomethane-based acid generator is used. In other words, although these acid generators generate acids that are weaker than those of onium salt-based acid generators, and are restricted in terms of the resists with which they can be used, in a positive resist composition of the present invention, these acid generators can be used quite satisfactorily.

As the component (B), either a single acid generator may be used alone, or a combination of two or more different acid generators may be used.

The quantity of the component (B) is typically within a range from 0.5 to 30 parts by weight, and even more preferably from 1 to 10 parts by weight, per 100 parts by weight of the component (A). Ensuring the quantity satisfies this range enables satisfactory pattern formation to be conducted. Furthermore, a uniform solution is obtained, and the storage stability is also favorable, both of which are desirable.

A positive resist composition of the present invention can be produced by dissolving the aforementioned components (A) and (B), and any of the optional materials described below, in an organic solvent (hereafter also referred to as the component (C).

The organic solvent of the component (C) may be any solvent capable of dissolving each of the components used to generate a uniform solution, and either one, or two or more solvents selected from known materials used as the solvents for conventional chemically amplified resists can be used.

Suitable examples include lactones such as γ-butyrolactone, ketones such as acetone, methyl ethyl ketone, cyclohexanone, methyl isoamyl ketone and 2-heptanone, polyhydric alcohols and derivatives thereof such as ethylene glycol, ethylene glycol monoacetate, diethylene glycol, diethylene glycol monoacetate, propylene glycol, propylene glycol monoacetate, dipropylene glycol, or the monomethyl ether, monoethyl ether, monopropyl ether, monobutyl ether or monophenyl ether of dipropylene glycol monoacetate, cyclic ethers such as dioxane, and esters such as methyl lactate, ethyl lactate (EL), methyl acetate, ethyl acetate, butyl acetate, methyl pyruvate, ethyl pyruvate, methyl methoxypropionate, and ethyl ethoxypropionate.

These organic solvents may be used either alone, or as a mixed solvent of two or more different solvents.

Furthermore, a mixed solvent of propylene glycol monomethyl ether acetate (PGMEA) and a polar solvent is preferred. In such cases, the mixing ratio (weight ratio) can be determined on the basis of the co-solubility of the PGMEA and the polar solvent, but is preferably within a range from 1:9 to 9:1, and even more preferably from 2:8 to 8:2.

More specifically, in those cases where EL is added as the polar solvent, the weight ratio of PGMEA:EL is preferably within a range from 1:9 to 9:1, and even more preferably from 2:8 to 8:2.

Furthermore, as the organic solvent, a mixed solvent of at least one of PGMEA and EL, together with γ-butyrolactone is also preferred. In such cases, the mixing ratio is set so that the weight ratio between the former and latter components is preferably within a range from 70:30 to 95:5.

There are no particular restrictions on the quantity used of the component (C), which is set in accordance with the desired film thickness so as to produce a concentration that enables favorable application to a substrate or the like, and is typically sufficient to produce a solid fraction concentration within the resist composition of 2 to 20% by weight, and preferably from 5 to 15% by weight. The solid fraction concentration of the resist composition can be adjusted appropriately within this range from 3 to 30% by weight, in accordance with the desired resist film thickness.

In the positive resist composition, in order to improve the resist pattern shape and the post exposure stability of the latent image formed by the pattern-wise exposure of the resist layer, a nitrogen-containing organic compound (D) (hereafter referred to as the component (D)) may be added as an optional component.

A multitude of these nitrogen-containing organic compounds have already been proposed, and any of these known compounds can be used, although secondary lower aliphatic amines and tertiary lower aliphatic amines are preferred.

Here, a lower aliphatic amine refers to an alkyl or alkyl alcohol amine of no more than 5 carbon atoms, and examples of these secondary and tertiary amines include trimethylamine, diethylamine, triethylamine, di-n-propylamine, tri-n-propylamine, tripentylamine, tridodecylamine, trioctylamine, diethanolamine, triethanolamine and triisopropanolamine, although alkanolamines such as triethanolamine are particularly preferred.

Furthermore, nitrogen-containing organic compounds represented by a general formula (VI) shown below can also be favorably employed.

NR¹¹—O—R¹²—O—R¹³)₃ (VI)

(wherein, R¹¹ and R¹² each represent, independently, a lower alkylene group, and R¹³ represents a lower alkyl group)

R¹¹, R¹² and R¹³ may be straight chains, branched chains, or cyclic structures, although straight chains and branched chains are preferred.

From the viewpoint of regulating the molecular weight, the number of carbon atoms within each of R¹¹, R¹² and R¹³ is typically within a range from 1 to 5, and is preferably from 1 to 3. The number of carbon atoms in R¹¹, R¹² and R¹³ may be either the same or different. Moreover, the structures of R¹¹ and R¹² may be either the same or different.

Examples of compounds represented by the general formula (VI) include tris-(2-methoxymethoxyethyl)amine, tris-2-(2-methoxy(ethoxy))ethylamine, and tris-(2-(2-methoxyethoxy)methoxyethyl)amine. Of these, tris-2-(2-methoxy(ethoxy))ethylamine is preferred.

Of the above nitrogen-containing organic compounds, compounds represented by the general formula (VI) are preferred, and tris-2-(2-methoxy(ethoxy))ethylamine in particular has minimal solubility in the solvents used in immersion lithography processes, and is consequently preferred.

These compounds can be used either alone, or in combinations of two or more different compounds.

The component (D) is typically added in a quantity within a range from 0.01 to 5.0 parts by weight per 100 parts by weight of the component (A).

Furthermore, in order to prevent any deterioration in sensitivity caused by the addition of the aforementioned component (D), and improve the resist pattern shape and the post exposure stability of the latent image formed by the pattern-wise exposure of the resist layer, an organic carboxylic acid, or a phosphorus oxo acid or derivative thereof (E) (hereafter referred to as the component (E)) may also be added as an optional component to a positive resist composition of the present invention. Either one, or both of the component (D) and the component (E) can be used.

Examples of suitable organic carboxylic acids include malonic acid, citric acid, malic acid, succinic acid, benzoic acid, and salicylic acid.

Examples of suitable phosphorus oxo acids or derivatives thereof include phosphoric acid or derivatives thereof such as esters, including phosphoric acid, di-n-butyl phosphate and diphenyl phosphate; phosphonic acid or derivatives thereof such as esters, including phosphonic acid, dimethyl phosphonate, di-n-butyl phosphonate, phenylphosphonic acid, diphenyl phosphonate and dibenzyl phosphonate; and phosphinic acid or derivatives thereof such as esters, including phosphinic acid and phenylphosphinic acid, and of these, phosphonic acid is particularly preferred.

The component (E) is typically used in a quantity within a range from 0.01 to 5.0 parts by weight per 100 parts by weight of the component (A).

Other miscible additives can also be added to a positive resist composition of the present invention according to need, and examples include additive resins for improving the performance of the resist film, surfactants for improving the coating properties, dissolution inhibitors, plasticizers, stabilizers, colorants, halation prevention agents, and dyes and the like.

Production of a positive resist composition of the present invention can be conducted by simply mixing and stirring each of the components together using conventional methods, and where required, the composition may also be mixed and dispersed using a dispersion device such as a dissolver, a homogenizer, or a triple roll mill. Furthermore, following mixing, the composition may also be filtered using a mesh or a membrane filter or the like.

### <<Method of Forming Resist Pattern>>

Next is a description of a method of forming a resist pattern according to the present invention.

First, a resist composition according to the present invention is applied to the surface of a substrate such as a silicon wafer using a spinner or the like, and a prebake (PAB treatment) is then performed.

An organic or inorganic anti-reflective film may also be provided between the substrate and the applied layer of the resist composition, creating a 2-layer laminate.

Furthermore, a 2-layer laminate in which an organic anti-reflective film is provided on top of the applied layer of the resist composition can also be formed, and a 3-layer laminate comprising an additional bottom layer anti-reflective film can also be formed.

The steps up until this point can be conducted using conventional techniques. The operating conditions and the like are preferably set in accordance with the makeup and the characteristics of the resist composition being used.

Subsequently, the resist layer formed from the applied film of the resist composition obtained above is subjected to selective liquid immersion lithography through a desired mask pattern. At this time, the region between the resist layer and the lens at the lowermost point of the exposure apparatus is pre-filled with a solvent that has a larger refractive index than the refractive index of air, and the exposure is preferably conducted with this region filled with a solvent which exhibits a refractive index that is larger than the refractive index of air but smaller than the refractive index of the resist layer.

There are no particular restrictions on the wavelength used for the exposure, and an ArF excimer laser, KrF excimer laser, F₂ laser, or other radiation such as EUV (extreme ultraviolet), VUV (vacuum ultraviolet), electron beam, X-ray or soft X-ray radiation can be used. A resist composition according to the present invention is particularly useful for KrF or ArF excimer lasers, and is particularly effective for ArF excimer lasers.

As described above, in a formation method of the present invention, during exposure the region between the resist layer and the lens at the lowermost point of the exposure apparatus is preferably filled with a solvent which exhibits a refractive index that is larger than the refractive index of air but smaller than the refractive index of the resist composition being used.

Examples of this solvent which exhibits a refractive index that is larger than the refractive index of air but smaller than the refractive index of the resist composition being used include water and fluorine-based inert liquids.

Specific examples of these fluorine-based inert liquids include liquids containing a fluorine-based compound such as C₃HCl₂F₅, C₄F₉OCH₃, C₄F₉OC₂H₅ or C₅H₃F₇ as the primary component, or perfluoroalkyl compounds with a boiling point within a range from 70 to 180° C. and preferably from 80 to 160° C. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

Amongst these fluorine-based inert liquids, liquids with a boiling point that falls within the above range enable the removal of the medium used as the immersion liquid following completion of the exposure to be performed using a simple method, and are consequently preferred.

A resist composition of the present invention is particularly resistant to any adverse effects caused by water, and because the resulting sensitivity and shape of the resist pattern profile are excellent, water is preferably used as the solvent which exhibits a refractive index that is larger than the refractive index of air. Furthermore, water is also preferred in terms of cost, safety, environmental friendliness, and general flexibility.

Furthermore, there are no particular restrictions on the refractive index of the solvent, provided it is larger than the refractive index of air but smaller than the refractive index of the resist composition being used.

Subsequently, following completion of the exposure step, PEB (post exposure baking) is conducted, and then a developing treatment is performed using an alkali developing liquid formed from an aqueous alkali solution. The substrate is then preferably rinsed with pure water. This water rinse is conducted by dripping or spraying water onto the surface of the substrate while it is rotated, and washes away the developing solution and those portions of the resist composition that have been dissolved by the developing solution. By conducting a subsequent drying treatment, a resist pattern is obtained in which the film of the resist composition has been patterned into a shape corresponding with the mask pattern.

In this manner, by using a positive resist composition for immersion exposure and a method of forming a resist pattern according to the present invention, a resist pattern with an ultra fine line width, for example a line and space (L&S) pattern with a resist pattern width of 90 nm or less such as an ultra fine resist pattern of approximately 65 nm, can be formed.

In immersion lithography, because the resist layer comes in contact with the solvent during the immersion exposure as described above, it is thought that a variety of problems may arise, including degeneration of the resist layer, and leaching of components from the resist that have an adverse effect on the solvent, thereby altering the refractive index of the solvent and impairing the inherent advantages offered by the immersion lithography process. In actual tests, a variety of problems have been confirmed, including deterioration in the sensitivity, and roughening of the surface of the resist pattern (a deterioration in the profile shape) such as the formation of T-top shaped resist patterns, and particularly in those cases where so-called acetal-based acid-dissociable, dissolution-inhibiting groups are used, including alkyloxyalkyl groups such as ethoxyethyl groups, although a pattern is able to be formed, surface roughness is generated, and the rectangular formability of the resist pattern is unsatisfactory. It is thought that the reason for these observations is that the reaction that leads to the dissociation of the acetal-based acid-dissociable, dissolution-inhibiting groups is significantly affected by the solvent such as water used in the immersion exposure process.

In contrast, in the positive resist composition for immersion exposure of the present invention, despite the fact that the acid-dissociable, dissolution-inhibiting group (I) is an acetal-based acid-dissociable, dissolution-inhibiting group, it is resistant to the effects of immersion solvents (and particularly water), exhibits a powerful inhibiting effect on dissolution of the component (A) in the alkali developing solution prior to exposure, and dissociates readily (undergoes deprotection) from the alkali-soluble group following the exposure and PEB (post exposure baking) processes, meaning alkali solubility manifests readily. As a result, the alkali solubility varies significantly from pre-exposure to post-exposure, and it is surmised that this enables the formation of an ultra fine resist pattern with excellent resolution. Furthermore, the resist pattern can also be formed with no surface roughness and favorable rectangular formability.

Furthermore, a positive resist composition for immersion exposure of the present invention also exhibits excellent sensitivity.

Furthermore, because the acid-dissociable, dissolution-inhibiting group (I) includes an aliphatic cyclic group, the positive resist composition for immersion exposure of the present invention is also expected to offer excellent etching resistance.

### EXAMPLES

As follows is a description of examples of the present invention, although the scope of the present invention is in no way limited by these examples.

### Synthesis Example 1

### Synthesis of Compound 59 (2-adamantyl chloromethyl ether)

Paraformaldehyde was added to 2-hydroxyadamantane, a 2.5 equivalence of hydrogen chloride gas relative to the 2-hydroxyadamantane was blown through the mixture, and a reaction was conducted at 50° C. for 12 hours. Following completion of the reaction, the product was distilled under reduced pressure, yielding a compound 59 (2-adamantyl chloromethyl ether) represented by the formula (59) shown below.

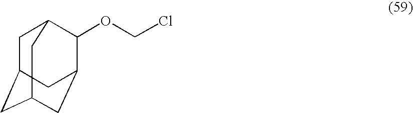

### Synthesis Example 2

### Synthesis of Compound 61 (2-adamantyloxymethyl methacrylate)

6.9 g of methacrylic acid was dissolved in 200 mL of tetrahydrofuran, and 8.0 g of triethylamine was then added. Following stirring at room temperature, a solution containing 15 g of the compound 59 dissolved in 100 mL of tetrahydrofuran was added dropwise to the mixture. The resulting mixture was stirred for 12 hours at room temperature, and the precipitated salt was removed by filtration. The solvent was removed by evaporation from the thus obtained distillate, the residue was subsequently dissolved in 200 mL of ethyl acetate and washed with pure water (100 mL×3), and the solvent was then removed by evaporation. Upon cooling in ice, a white solid was obtained. This compound was termed compound 61. The compound 61 is represented by a formula (61) shown below.

The results of measuring the infrared absorption spectrum (IR) and the proton nuclear magnetic resonance spectrum (¹H-NMR) were as follows. IR (cm⁻¹): 2907, 2854 (C—H stretch), 1725 (C═O stretch), 1638 (C═C stretch). ¹H-NMR (CDCl₃, internal standard: tetramethylsilane) ppm: 1.45 to 2.1 (m, 17H), 3.75 (s, 1H), 5.45 (s, 2H), 5.6 (s, 1H), 6.12 (s, 1H).

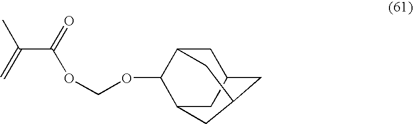

### Resin Synthesis Example 1

3.0 g of the compound 61 and 2.0 g of γ-butyrolactone methacrylate were dissolved in 45 mL of tetrahydrofuran, and 0.20 g of azobisisobutyronitrile was added. Following refluxing for 12 hours, the reaction solution was added dropwise to 2 L of methanol. The precipitated resin was collected by filtration and dried under reduced pressure, yielding a white resin powder. This resin was termed resin 1, and the structural formula for the resin is represented by a formula (64) shown below. The molecular weight (Mw) of the resin 1 was 12,300, and the polydispersity (Mw/Mn) was 1.96. Furthermore, measurement of the carbon-13 nuclear magnetic resonance spectrum (¹³C-NMR) revealed a compositional ratio of m:n=0.47:0.53.

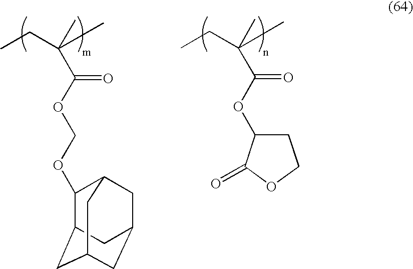

### Example 1

### Evaluation of ArF Immersion Lithography

100 parts by weight of the resin 1, 3 parts by weight of triphenylsulfonium nonafluorobutanesulfonate (TPS-PFBS), and 0.3 parts by weight of triethanolamine were dissolved in 1330 parts by weight of propylene glycol monomethyl ether acetate (PGMEA), thus yielding a positive resist composition.

Subsequently, the positive resist composition obtained in this manner was used to conduct formation of a resist pattern.

First, an organic anti-reflective film composition ARC-29 (a product name, manufactured by Brewer Science Ltd.) was applied to the surface of a silicon wafer using a spinner, and the composition was then baked and dried on a hotplate at 215° C. for 60 seconds, thereby forming an organic anti-reflective film with a thickness of 77 nm.

Subsequently, the positive resist composition obtained above was applied to the surface of the anti-reflective film using a spinner, and was then prebaked and dried on a hotplate at 100° C. for 90 seconds, thereby forming a resist film with a film thickness of 150 nm on top of the anti-reflective film.

Subsequently, immersion lithography was conducted using a double beam interference lithography apparatus LEIES193-1 (manufactured by Nikon Corporation), by performing immersion double beam interference lithography using a prism, water and the interference of two light beams of 193 nm. The same method is disclosed in the aforementioned non-patent reference 2, and this method is widely known as a simple method of obtaining a line and space (L&S) pattern at the laboratory level.

Next, a PEB treatment was conducted at 100° C. for 90 seconds, and developing was then conducted for 60 seconds at 23° C. in an alkali developing solution. A 2.38% by weight aqueous solution of tetramethylammonium hydroxide was used as the developing solution.

Inspection of the thus obtained L&S pattern using a scanning electron microscope (SEM) revealed a resist pattern in which 65 nm lines and spaces had been formed at a ratio of 1:1. Furthermore, determination of the sensitivity (Eop) revealed a value of 7.0 mJ/cm².

Furthermore, the resist pattern did not have a T-top shape, but rather exhibited a high degree of rectangular formability.

### Example 2

A positive resist composition was prepared in the same manner as the example 1, and with the exception of altering the film thickness of the resist to 120 nm, the above evaluations were performed in the same manner as the example 1.

The results are shown in Table 1.

TABLE 1

| | Resist film | PEB | Res- | | |
|---|---|---|---|---|---|
| | thickness | temperature | olution | Sensitivity | |
| | (nm) | (° C.) | (nm) | (mJ/cm²) | Shape |
| Example 1 | 150 | 100 | 65 | 7.0 | Rectangular |
| Example 2 | 120 | 100 | 65 | 7.0 | Rectangular |

As is evident from the above results, the positive resist composition of the example 1 was able to form an ultra fine pattern of 65 nm. Furthermore, the sensitivity was high, and the shape was excellent. Moreover, no surface roughness was observed.

### INDUSTRIAL APPLICABILITY

The present invention can be applied to a positive resist composition for immersion exposure used in a method of forming a resist pattern that includes an immersion lithography step, and to a method of forming a resist pattern.

1. A positive resist composition for immersion exposure, comprising:
a resin component (A) that exhibits increased alkali solubility under action of acid; and
an acid generator component (B) that generates acid upon exposure, wherein
said resin component (A) includes a resin (A1) that has alkali-soluble groups (i) having a hydrogen atom, and in a portion of said alkali-soluble groups (i), said hydrogen atom is substituted with an acid-dissociable, dissolution-inhibiting group (I) represented by a general formula (I) shown below: 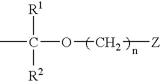
[wherein, Z represents an aliphatic cyclic group; n represents either 0 or an integer from 1 to 3; and R¹ and R² each represent, independently, a hydrogen atom or a lower alkyl group of 1 to 5 carbon atoms].

2. A positive resist composition for immersion exposure according to claim 1, wherein said alkali-soluble group (i) is at least one group selected from the group consisting of alcoholic hydroxyl groups, phenolic hydroxyl groups, and carboxyl groups.

3. A positive resist composition for immersion exposure according to claims 1 or 2, wherein said resin (A1) includes at least one structural unit selected from the group consisting of structural units represented by general formulas (a1-01) and (a1-02) shown below: 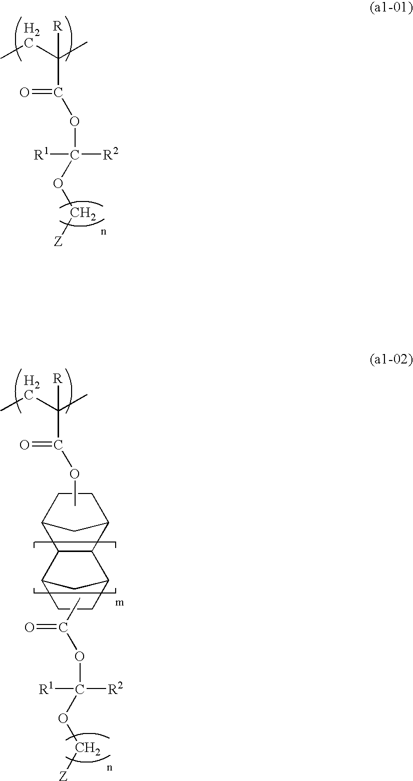
[wherein, Z represents an aliphatic cyclic group; n represents either 0 or an integer from 1 to 3; m represents either 0 or 1; each R group represents, independently, a hydrogen atom, a lower alkyl group of 1 to 5 carbon atoms, a fluorine atom, or a fluorinated lower alkyl group; and R¹ and R² each represent, independently, a hydrogen atom or a lower alkyl group of 1 to 5 carbon atoms].

4. A positive resist composition for immersion exposure according to claims 1 or 2, wherein said resin (A1) also includes a structural unit (a2) derived from an (α-lower alkyl)acrylate ester that contains a lactone-containing monocyclic or polycyclic group.

5. A positive resist composition for immersion exposure according to claims 1 or 2, further comprising: a nitrogen-containing organic compound (D).

6. A method of forming a resist pattern using a positive resist composition for immersion exposure according to claims 1 or 2, wherein said method includes conducting immersion exposure.
